(19) United States
(12) Patent Application Publication
(10) Pub. No.: US 2026/0188191 A1
(43) Pub. Date: Jul. 2, 2026

(54) DISPLAY DEVICE

(71) Applicant: LG Display Co., Ltd., Seoul (KR)

(72) Inventor: Youngjae LEE, Paju-si (KR)

(73) Assignee: LG Display Co., Ltd., Seoul (KR)

(21) Appl. No.: 19/356,609

(22) Filed: Oct. 13, 2025

(30) Foreign Application Priority Data
Dec. 30, 2024 (KR) 10-2024-0200115

(51) Int. Cl. G09G 3/32

(52) U.S. Cl. CPC G09G 3/32; G09G 2310/0267; G09G 2310/0291; G09G 2320/0223; G09G 2320/0233; G09G 2320/0247

(57) ABSTRACT

Embodiments relate to a display device including a display panel including a display area including pixels disposed therein, an optical area disposed within the display area, and a non-display area surrounding the display area, and a gate driver disposed in the non-display area and configured to apply scan signals to the pixels through a plurality of scan lines via a plurality of stage circuits connected in a cascade, each stage circuit comprises a node controller for charging or discharging a Q node and a QB node, and an output buffer including at least one buffer transistor and for outputting the scan signal in response to voltages of the Q node and the QB node, wherein the plurality of stage circuits include first group stage circuits and second group stage circuits, and a size of the at least one buffer transistor in the first group stage circuits is smaller than a size of the at least one buffer transistor in the second group stage circuits.

### CROSS REFERENCE TO RELATED APPLICATION

The present application claims priority to Korean Patent Application No. 10-2024-0200115, filed on December 30, 2024, the entire contents of which is incorporated herein for all purposes by this reference.

### BACKGROUND

### TECHNICAL FIELD

The present disclosure relates to a display device.

### DESCRIPTION OF THE RELATED ART

With the advancement of the information society, there is an increasing demand for display devices that can show images, and various types of display devices such as liquid crystal display (LCD) devices and organic light emitting diode (OLED) displays are being utilized.

A display device includes multiple components that provide various functions, such as a camera and optical sensors. In conventional display devices, these components were placed in the bezel area of the display panel. Recently, to implement bezel-less display devices, structures such as hole-in display (HID) or hole-in active area (HiAA), where the camera and optical sensors are positioned within the display area, have been adopted.

### BRIEF SUMMARY

The embodiments solve issues caused by the optical region, where the camera and optical sensors are positioned, in HID or HiAA structures.

The embodiments mitigate the kickback phenomenon in which the voltage of the gate electrode of a driving transistor is affected by a scan signal applied to the switching transistor of a pixel.

The embodiments solve the issue of increased luminance degradation caused by an increase in the kickback voltage of the gate electrode of the driving transistor in response to a scan signal around the optical region.

The embodiments provide a display device capable of reducing the kickback voltage by increasing the RC delay of the scan signal when applying the scan signal to pixels arranged adjacent to the optical region.

The embodiments provide a display device capable of increasing the RC delay of the scan signal by reducing the size of a buffer transistor in a stage circuit that applies the scan signal to pixels arranged adjacent to the optical region.

The embodiments provide a display device capable of gradually increasing and decreasing the size of the buffer transistor among a plurality of stage circuits that apply the scan signal to pixels arranged adjacent to the optical region.

The embodiments provide a display device capable of further reducing the size of the buffer transistor in stage circuits that apply the scan signal to pixels arranged adjacent to the column-direction edges of the optical region.

The embodiments provide a display device in which, within cascaded stage circuits applying the scan signal to pixels arranged adjacent to the optical region, the buffer transistors are designed to be smallest in the first and last stage circuits and largest in the middle stage circuit.

A display device according to an embodiment may include a display panel including a display area including pixels disposed therein, an optical area disposed within the display area, and a non-display area surrounding the display area, and a gate driver disposed in the non-display area and configured to apply scan signals to the pixels through a plurality of scan lines via a plurality of stage circuits connected in a cascade.

Each of the plurality of stage circuits may include a node controller configured to charge or discharge a Q node and a QB node in response to gate clock signals, and an output buffer including at least one buffer transistor and configured to output a gate high voltage or a gate low voltage as the scan signal in response to the voltages of the Q node and the QB node.

The plurality of stage circuits may include first group stage circuits and second group stage circuits, and the size of the at least one buffer transistor in the first group stage circuits may be smaller than the size of the at least one buffer transistor in the second group stage circuits.

The display area may include a first region overlapping with the optical area in a row direction, and a second region surrounding the first region.

The first group stage circuits may be configured to apply the scan signal to pixels disposed in the first region, and the second group stage circuits may be configured to apply the scan signal to pixels disposed in the second region.

The size of the at least one buffer transistor among the first group stage circuits varies gradually.

Among the first group stage circuits connected in a cascade, the size of the buffer transistor may increases gradually and then decrease gradually.

The size of the buffer transistor may inversely proportional to a resistive-capacitive (RC) delay of the scan signal.

Each of the pixels may include a light-emitting element, a driving transistor connected between a high-potential driving voltage line and the light-emitting element, with a gate electrode connected to a second node, and a switching transistor connected between a data line and the second node, with a gate electrode configured to receive the scan signal.

Based on the level of the scan signal transitioning, a voltage pre-stored at the second node may be kicked back by a predetermined kickback voltage.

The magnitude of the kickback voltage may be inversely proportional to the RC delay of the scan signal.

The switching transistor may have a dual-gate structure including a top gate electrode and a bottom gate electrode.

Each of the pixels may further include an emission transistor connected between the high-potential driving voltage line and the driving transistor.

The switching transistor may be an oxide thin-film transistor, and the emission transistor may be a low temperature poly-silicon (LTPS) thin-film transistor.

The display device may further include a substrate, a first insulating layer disposed on the substrate, a first semiconductor layer of the emission transistor disposed on the first insulating layer, a second insulating layer disposed on the first semiconductor layer, a gate electrode of the emission transistor disposed on the second insulating layer, a third insulating layer disposed on the gate electrode of the emission transistor, the bottom gate electrode of the switching transistor disposed on the third insulating layer, a fourth insulating layer disposed on the bottom gate electrode, a second semiconductor layer of the switching transistor disposed on the fourth insulating layer, a fifth insulating layer disposed on the second semiconductor layer, the top gate electrode of the switching transistor disposed on the fifth insulating layer, a sixth insulating layer disposed on the top gate electrode of the switching transistor, and source and drain electrodes of the emission transistor and the switching transistor disposed on the sixth insulating layer.

The bottom gate electrode may be composed of a high-resistance material, and the top gate electrode may be composed of a low-resistance material.

Each of the plurality of scan lines may include a first scan line composed of a low-resistance material and connected to the top gate electrode, and a second scan line composed of a high-resistance material and connected to the bottom gate electrode.

In the first region, the first scan line and the second scan line may be electrically connected through a contact hole.

In the first region, the first scan line may extend in a curved manner along an outer circumference of the optical area.

In the first region, the first scan lines may have different lengths.

The RC delay of the scan signal may be proportional to the length of the scan line.

The second scan line may be segmented into a plurality of portions on both sides of the optical area, and the segmented plurality of portions may be electrically connected to the first scan line through the contact hole on both sides of the optical area.

### BRIEF DESCRIPTION OF THE SEVERAL VIEWS OF THE DRAWINGS

FIG. 1 is a block diagram illustrating the configuration of a display device according to an embodiment;

FIG. 2 is a circuit diagram of a pixel according to an embodiment;

FIG. 3 is a diagram illustrating a driving method of the pixel of FIG. 2 according to an embodiment;

FIG. 4 is a plan view illustrating the configuration of a display panel according to an embodiment;

FIG. 5 is a schematic cross-sectional of a display panel according to an embodiment;

FIG. 6 is an enlarged plan view of the optical region of FIG. 4, schematically showing the scan lines around the optical region;

FIG. 7 is a schematic cross-sectional view of the contact hole area of FIG. 6;

FIG. 8 is a diagram for explaining the kickback variation of the second node due to RC delay differences;

FIG. 9 is a diagram illustrating the luminance distribution between pixel rows around the optical region;

FIG. 10 is a block diagram illustrating the configuration of a gate driver according to an embodiment;

FIG. 11 is a diagram illustrating the configuration of a shift register according to an embodiment;

FIG. 12 is a circuit diagram illustrating the configuration of the stage circuit according to an embodiment;

FIG. 13 is a plan view illustrating the structure of the transistor according to an embodiment;

FIG. 14 is a graph illustrating the relationship between the size of the transistor and the RC delay of the output signal according to an embodiment; and

FIG. 15 is a diagram illustrating the size distribution of the transistor between cascaded stage circuits according to an embodiment.

### DETAILED DESCRIPTION

Hereinafter, embodiments will be described with reference to accompanying drawings. In the specification, when a component (or area, layer, part, etc.) is mentioned as being “on top of,” “connected to,” or “coupled to” another component, it means that it may be directly connected/coupled to the other component, or a third component may be placed between them.

The same reference numerals refer to the same components. In addition, in the drawings, the thickness, proportions, and dimensions of the components are exaggerated for effective description of the technical content. The expression “and/or” is taken to include one or more combinations that can be defined by associated components.

The terms “first,” “second,” etc., are used to describe various components, but the components should not be limited by these terms. The terms are used only for distinguishing one component from another component. For example, a first component may be referred to as a second component and, similarly, the second component may be referred to as the first component, without departing from the scope of the present disclosure. The singular forms are intended to include the plural forms as well unless the context clearly indicates otherwise.

The terms such as “below,” “lower,” “above,” “upper,” etc., are used to describe the relationship of components depicted in the drawings. The terms are relative concepts and are described based on the direction indicated on the drawing.

It will be further understood that the terms “comprises,” “has,” and the like are intended to specify the presence of stated features, numbers, steps, operations, components, parts, or a combination thereof but are not intended to preclude the presence or possibility of one or more other features, numbers, steps, operations, components, parts, or combinations thereof.

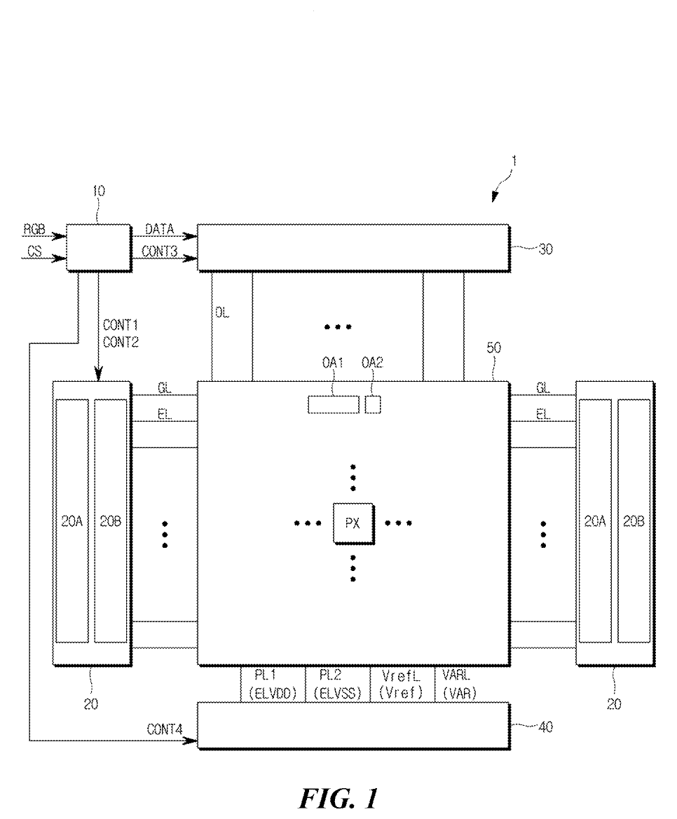

FIG. 1 is a block diagram illustrating a configuration of a display device according to an embodiment.

Referring to FIG. 1, the display device 1 includes a timing controller 10, a gate driver 20, a data driver 30, a power supply unit 40, and a display panel 50.

The timing controller 10 may receive video signals RGB and control signals CS from external host systems or the like. The video signal RGB may include a plurality of grayscale data. The control signals CS may include a horizontal sync signal, a vertical sync signal, and a main clock signal.

The timing control unit 10 processes the video signals RGB and control signals CS to suit the operating conditions of the display panel 50, thereby generating and outputting image data DATA, a gate driving control signal CONT1, an emission driving control signal CONT2, a data driving control signal CONT3, and a power supply control signal CONT4.

The gate driver 20 may include a scan driving circuit 20A that generates scan signals based on the gate drive control signal CONT1 input from the timing controller 10. The scan driving circuit 20A may provide the generated scan signals to the pixels PX through a plurality of scan lines GL. In one embodiment, a single pixel PX may be configured to receive a plurality of scan signals with different waveforms. In this embodiment, the scan driving circuit 20A may provide the plurality of scan signals to the pixels PX of the corresponding pixel rows through the scan lines GL.

The gate driver 20 may further include an emission driving circuit 20B that generates emission control signals based on the emission driving control signal CONT2 input from the timing controller 10. The emission driving circuit 20B may provide the generated emission control signals to the pixels PX of the corresponding pixel rows through emission lines EL.

The gate driver 20 may be configured in a Gate In Panel (GIP) form, implemented on the display panel 50. The gate driver 20 may be disposed on one side of the display panel 50 or, as shown in the drawing, on both sides (e.g., left and right) of the display panel 50. Depending on the driving method, panel design method, etc., the gate driver 20 may be disposed on both sides (e.g., left and right) of the display panel 50, as shown in the drawing, or may be connected to two or more of the four sides of the display panel 50.

The data driver 30 may generate data signals based on the image data DATA and data driving control signal CONT3 output from the timing controller 10. The data driver 30 may provide the generated data signals to the pixels PX through multiple data lines DL.

The power supply unit 40 may generate a high-potential driving voltage ELVDD and a low-potential driving voltage ELVSS to be provided to the display panel 50 based on the power supply control signal CONT4. The power supply unit 40 may provide the generated driving voltages ELVDD and ELVSS to the pixels PX through the corresponding voltage lines PL1 and PL2. Additionally, the power supply unit 40 may further generate a reference voltage Vref and/or an anode reset voltage VAR (also referred to as bias voltage) required for driving the pixels PX, and provide the voltages to the pixels PX through the corresponding voltage lines VrefL and VARL.

The display panel 50 includes a plurality of pixels PX (or sub-pixels) arranged thereon. The pixels PX may be arranged in a matrix form on the display panel 50, for example. The pixels PX arranged in a single pixel row may be connected to the same scan line GL and emission line EL, and the pixels PX arranged in a single pixel column may be connected to the same data line DL. The pixels PX may emit light with corresponding luminance in response to the emission control signal applied through the emission line EL, according to the scan signals and data signals supplied through the scan line GL and data line DL.

In one embodiment, each pixel PX may display one of the colors, red, green, or blue. In another embodiment, each pixel PX may display one of the colors, cyan, magenta, or yellow. In various embodiments, each pixel PX may display one of the colors, red, green, blue, or white.

In one embodiment, the display panel 50 may include one or more optical regions OA. One or more optical regions OA may be arranged overlapping with one or more optoelectronic devices, such as imaging devices like a camera (image sensor), proximity sensors, and ambient light sensors.

In one embodiment, the display device 1 may be driven in a variable refresh rate mode, where the driving frequency may be adjusted. For example, the display device 1 may be driven at a refresh rate higher or lower than a predetermined reference refresh rate. When the display device 1 is driven at a rate lower than the reference refresh rate, it may be referred to as “low-speed driving,” and when driven at a rate higher than the reference refresh rate, it may be referred to as “high-speed driving.” The refresh rate may be determined based on the type of image being displayed, but is not limited thereto.

The timing controller 10 may generate control signals CONT1 to CONT4 so that the pixels PX may be driven at various refresh rates. For example, the timing controller 10 may change the frequency of the clock signal included in the control signals CONT1 to CONT4, adjust the timing of the horizontal synchronization signal or vertical synchronization signal, or drive the gate driver 20 in a mask mode, thereby varying the refresh rate.

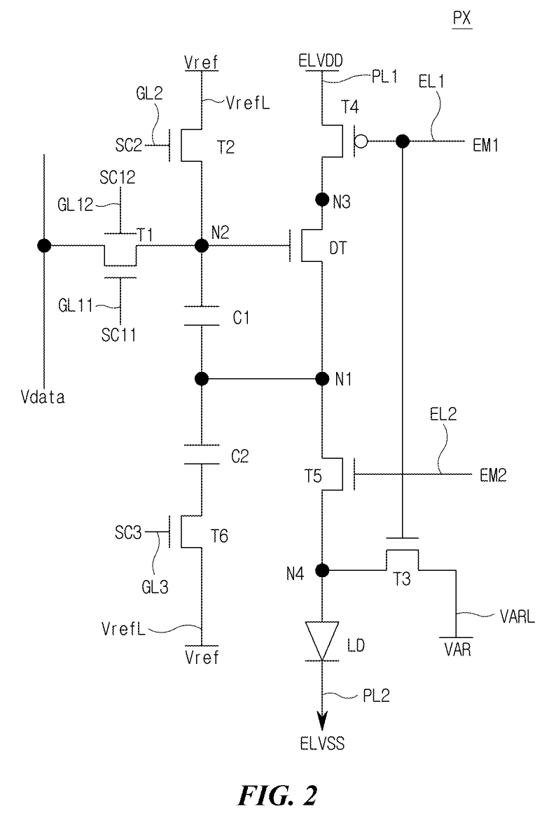

FIG. 2 is a circuit diagram of a pixel according to an embodiment;

Referring to FIG. 2, the pixel PX according to an embodiment may include a driving transistor DT, a light-emitting element LD connected to the driving transistor DT, and a control circuit for controlling the amount of driving current to be applied to the light-emitting element LD through the driving transistor DT. For example, the control circuit may include transistors T1 to T6 and capacitors C1 and C2.

The first electrode of the driving transistor DT is configured to receive the high-potential drive voltage ELVDD through the third node N3 and is connected to the high-potential drive voltage line PL1, while the second electrode is connected to the light-emitting element LD through the first node N1. The gate electrode of the driving transistor DT is connected to the second node N2. The driving transistor DT may turn on based on the voltage applied to the second node N2, thereby controlling the amount of driving current flowing from the high-potential driving voltage ELVDD to the light-emitting element LD.

The first electrode of the first transistor T1 is connected to the data line DL, and the second electrode is connected to the gate electrode of the driving transistor DT through the second node N2. The gate electrode of the first transistor T1 is connected to the first scan lines GL11 and GL12, allowing it to receive the first scan signals SC11 and SC12. The first transistor T1 is turned on according to the first scan signals SC11 and SC12 applied to the first scan lines GL11 and GL12, and can transfer the data voltage Vdata applied to the data line DL to the second node N2. The first transistor T1 may be referred to as a switching transistor.

The first electrode of the second transistor T2 is configured to receive the reference voltage Vref (connected to the reference voltage line VrefL), and the second electrode is connected to the second node N2. The gate electrode of the second transistor T2 is connected to the second scan line GL2 to receive the second scan signal SC2. The second transistor T2 may be turned on according to the second scan signal SC2 applied to the second scan line GL2 and transmit the reference voltage Vref to the second node N2. This second transistor T2 may be referred to as an initialization transistor.

The first electrode of the third transistor T3 is configured to receive the anode reset voltage VAR (connected to the anode reset voltage line VARL), and the second electrode is connected to the anode electrode of the light-emitting element LD through the fourth node N4. The gate electrode of the third transistor T3 is connected to the first emission line EL1 to receive the first emission signal EM1. The third transistor T3 may turn on according to the first emission signal EM1 applied to the first emission line EL1, thereby transmitting the anode reset voltage VAR to the anode electrode of the light-emitting element LD. This third transistor T3 may be referred to as an anode reset transistor.

The first electrode of the fourth transistor T4 is configured to receive a high voltage driving voltage ELVDD (connected to the high voltage driving voltage line PL1), and the second electrode is connected to the driving transistor DT via the first node N3. The gate electrode of the fourth transistor T4 is connected to the first emission line EL1 and may receive the first emission signal EM1. The fourth transistor T4 may connect the high-potential driving voltage line PL1 and the driving transistor DT in response to the first emission signal EM1 applied to the first emission line EL1.

The first electrode of the fifth transistor T5 is connected to the driving transistor DT via the first node N1, and the second electrode is connected to the light-emitting element LD via the fourth node N4. The gate electrode of the fifth transistor T5 is connected to the second emission line EL2 and may receive the second emission signal EM2. The fifth transistor T5 may connect the driving transistor DT and the light-emitting element LD in response to the second emission signal EM2 applied to the second emission line EL2.

When the fourth transistor T4 and the fifth transistor T5 are turned on, a current path is formed between the high voltage driving voltage ELVDD and the low voltage driving voltage ELVSS, and driving current flows through the light-emitting element LD, causing the light-emitting element LD to emit light. The fourth transistor T4 and the fifth transistor T5 may be referred to as emission transistors.

The sixth transistor T6 is connected between the second capacitor C2 and the reference voltage line VrefL. The gate electrode of the sixth transistor T6 is connected to the third scan line GL3 to receive the third scan signal SC3. The sixth transistor T6 may turn on in response to the third scan signal SC3 applied to the third scan line GL3 and may transfer the reference voltage Vref to the second capacitor C2. The sixth transistor T6 may be referred to as a compensation transistor.

The first capacitor C1 is connected between the first node N1 and the second node N2. The first capacitor C1 may store a voltage corresponding to the voltage difference between the first node N1 and the second node N2. For example, the first capacitor C1 may store a voltage corresponding to the voltage difference between the data voltage Vdata applied to the data line DL and the voltage at the second node N2, and maintain the stored voltage throughout a frame period, thereby stabilizing the voltage at the gate electrode of the driving transistor DT (i.e., the second node N2). The first capacitor C1 may be referred to as a storage capacitor.

The second capacitor C2 is connected between the first node N1 and the sixth transistor T6. The second capacitor C2 may store a voltage corresponding to the voltage difference between the first node N1 and the reference voltage Vref when the sixth transistor T6 turns on. In one embodiment, the second capacitor C2 may store the voltage value of the threshold voltage Vth of the driving transistor DT to compensate for the driving characteristics of the driving transistor DT. For example, the second capacitor C2 may store the voltage value of the threshold voltage Vth of the driving transistor DT during the sampling and programming period when the light-emitting element LD, described later, does not emit light (e.g., while the fifth transistor T5 is turned off). This second capacitor C2 may be referred to as a compensation capacitor.

The light-emitting element LD may have its anode electrode connected to the fourth node N4, and its cathode electrode may be connected to the low-potential drive voltage line PL2 (configured to receive the low-potential drive voltage ELVSS). When the driving transistor DT, the fourth transistor T4, and the fifth transistor T5 are turned on, a current path is formed between the high voltage driving voltage ELVDD and the low voltage driving voltage ELVSS, allowing driving current to flow through the light-emitting element LD. The light-emitting device LD may emit light with luminance corresponding to the amount of drive current applied.

In the embodiment of FIG. 2, the pixel PX may include an oxide semiconductor thin-film transistor. The oxide semiconductor thin-film transistor includes a gate electrode, a source electrode, and a drain electrode. The oxide semiconductor thin-film transistor includes an active layer formed of an oxide semiconductor. Here, the oxide semiconductor may be set as an amorphous or crystalline oxide semiconductor. The oxide semiconductor thin-film transistor may be configured as an N-type transistor. The oxide semiconductor thin-film transistor may be fabricated using a low-temperature process and has a lower charge mobility compared to the LTPS thin-film transistor. Such an oxide semiconductor thin-film transistor has excellent off-state current characteristics.

In an embodiment, the driving transistor DT may be formed as an oxide semiconductor thin-film transistor. At least one of the transistors T2 to T6 may be formed as an oxide semiconductor thin-film transistor.

Furthermore, in one embodiment, the pixel PX may be a hybrid type further including a low temperature poly-silicon (LTPS) thin-film transistor.

The LTPS thin-film transistor includes a gate electrode, a source electrode, and a drain electrode. The LTPS thin-film transistor has an active layer formed of polysilicon. Such an LTPS thin-film transistor may be configured as a P-type thin-film transistor. The LTPS thin-film transistor has a high electron mobility, resulting in fast driving characteristics.

In the embodiment of FIG. 2, the fourth transistor T4 is configured as an LTPS thin-film transistor. Due to the fourth transistor T4 being configured as an LTPS thin-film transistor with fast driving characteristics, when the first emission signal EM1 is applied at the turn-on level, the fourth transistor T4 may turn on quickly, and the emission response speed of the light-emitting device LD may increase.

When the third transistor T3 is an oxide thin-film transistor and the fourth transistor T4 is a thin-film transistor, the turn-on level of the third transistor T3 is high, and the turn-on level of the fourth transistor T4 is low. Therefore, when the first emission signal EM1 is applied at a high level, the third transistor T3 turns on, and the fourth transistor T4 turns off. In contrast, when the first emission signal EM1 is applied at a low level, the third transistor T3 turns off, and the fourth transistor T4 turns on. Thus, the third transistor T3 and fourth transistor T4 may be configured to alternate between turning on and turning off.

However, this embodiment is not limited thereto. That is, in various other embodiments, except for the third transistor T3, at least one of the driving transistor DT and other transistors T1, T2, and T6 may be further configured as an LTPS thin-film transistor.

Meanwhile, at least one of the transistors DT, T1 to T6 may have a dual-gate structure in which the gate electrode is formed on both the upper and lower sides of the semiconductor layer or semiconductor pattern. For example, the first transistor T1 may be formed in a dual-gate structure. In this embodiment, the top gate electrode 115′ and bottom gate electrode 115′′ of the first transistor T1 are connected to the first scan lines GL11 and GL12, respectively, and may receive the first scan signals SC11 and SC12.

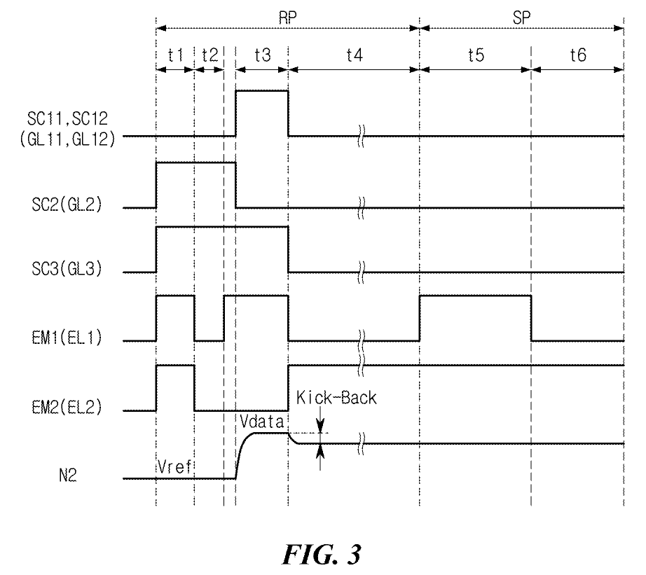

FIG. 3 is a diagram illustrating a driving method of the pixel of FIG. 2 according to an embodiment.

Referring to FIGS. 2 and 3, in the variable refresh rate mode, one frame (1 Frame) may be composed of a combination of at least one refresh period RP and at least one skip period SP.

The refresh period RP may include an initialization period t1, a sampling period t2, a programming period t3, and an emission period t4.

During the initialization period t1, the second scan signal SC2 and the third scan signal SC3 at a turn-on level are applied, turning on the second transistor T2 and the sixth transistor T6. Additionally, during the initialization period t1, the first light-emission signal EM1 at a high level and the second light-emission signal EM2 at a turn-on level are applied, turning on the third transistor T3 and the fifth transistor T5.

When the reference voltage Vref is applied to the second node N2 through the turned-on second transistor T2, the gate electrode of the driving transistor DT may be initialized to the reference voltage Vref. The reference voltage Vref may be a low-level positive voltage and may correspond to a black luminance voltage, but this is not limited thereto.

When the anode reset voltage VAR is applied to the fourth node N4 through the turned-on third transistor T3, the anode electrode of the light-emission element LD may be initialized to the anode reset voltage VAR. The anode reset voltage VAR is further applied to the first node N1 through the fifth transistor T5. The anode reset voltage VAR may be the same as or different from the reference voltage Vref. For example, the anode reset voltage VAR may be lower than the reference voltage Vref or may be a negative voltage, but is not limited thereto.

The first capacitor C1 stores a voltage corresponding to the difference between the second node N2 and the first node N1. That is, during the initialization period t1, the first capacitor C1 may store a voltage Vref-VAR corresponding to the difference between the reference voltage Vref and the anode reset voltage VAR.

When the sixth transistor T6 is in a turned-on state, the second capacitor C2 stores a voltage corresponding to the difference between the first node N1 and the reference voltage Vref. That is, during the initialization period t1, the second capacitor C2 may store a voltage VAR-Vref corresponding to the difference between the anode reset voltage VAR and the reference voltage Vref.

During the sampling period t2, the first light-emission signal EM1 transitions to a low level, turning on the fourth transistor T4 and turning off the third transistor T3. Additionally, the second light-emission signal EM2 transitions to a turn-off level, turning off the fifth transistor T5.

When the high-potential drive voltage ELVDD is applied to the third node N3 through the turned-on fourth transistor T4, the high-potential drive voltage ELVDD may be applied to the drain electrode of the driving transistor DT. The reference voltage Vref is applied to the gate electrode of the driving transistor DT through the second transistor T2. The source electrode of the driving transistor DT becomes a voltage-variable state.

As a result, during the sampling period t2, the driving transistor DT may be turned on and operate in a source follower configuration. That is, the driving transistor DT may supply a drain-source current to the first node N1 until the gate-source voltage reaches the threshold voltage Vth of the driving transistor DT. The voltage of the first node N1 gradually increases from the anode reset voltage VAR and may converge to a voltage corresponding to the difference between the reference voltage Vref and the threshold voltage Vth (Vref-Vth).

The first capacitor C1 stores a voltage corresponding to the difference between the second node N2 and the first node N1. After the driving transistor DT enters saturation, the first capacitor C1 may store the threshold voltage Vth, which corresponds to the difference between the voltage of the first node N1, i.e., Vref-Vth, and the reference voltage Vref.

The second capacitor C2 stores a voltage corresponding to the difference between the first node N1 and the reference voltage Vref. After the driving transistor DT enters saturation, the second capacitor C2 may store the threshold voltage Vth, which corresponds to the difference between the voltage of the first node N1, i.e., Vref-Vth, and the reference voltage Vref.

During the programming period t3, the second scan signal SC2 transitions to a turn-off level, and the first light emission signal EM1 transitions to a high level, causing the second transistor T2 and the fourth transistor T4 to be turned off, while the third transistor T3 is turned on. Additionally, during the programming period t3, the first scan signals SC11 and SC12 are applied at a turn-on level, turning on the first transistor T1.

When the data voltage Vdata is applied to the second node N2 through the turned-on first transistor T1, the data voltage Vdata may be applied to the gate electrode of the driving transistor DT. During the programming period t3, the voltage at the first node N1 may be maintained at the threshold voltage Vth by the second capacitor C2.

The first capacitor C1 stores a voltage corresponding to the difference between the second node N2 and the first node N1. That is, during the programming period t3, the first capacitor C1 may store the voltage corresponding to the difference between the data voltage Vdata and the threshold voltage Vth (Vdata-Vth).

During the emission period t4, the first to third scan signals SC11 to SC3 are switched to the turn-off level, turning off the first, second, and sixth transistors T1, T2, and T6. Additionally, during the emission period t4, the first emission signal EM1 at a low level and the second emission signal EM2 at a turn-on level are applied, turning on the fourth and fifth transistors T4 and T5.

Through the turned-on fourth and fifth transistors T4 and T5, a current path may be formed from the high-potential drive voltage ELVDD through the driving transistor DT to the light-emitting element LD. As a result, the driving current corresponding to the programmed voltage in the driving transistor DT is provided to the light-emitting element LD to emit light at the corresponding brightness.

Here, the programmed voltage in the driving transistor DT is the voltage programmed in the first capacitor C1, which is the data voltage Vdata compensated by the threshold voltage Vth. Therefore, the degradation of the driving transistor DT may be compensated.

Meanwhile, during the emission period t4, when the fifth transistor T5 turns on, the voltage at the first node N1 may change rapidly. When a second capacitor C2 with a large electrical capacitance is electrically connected to the respective nodes, voltage coupling may occur between the first node N1 and the second capacitor C2. This may interfere with the voltage fluctuation at the first node N1, and delay may occur until the emission device LD emits with the desired luminance. Furthermore, when the voltage at the first node N1 fluctuates due to voltage coupling, distortion may occur in the voltage of the second node N2, which is indirectly connected to the first node N1, causing the source-gate voltage of the driving transistor DT to fail to be maintained stably.

In the embodiment described above, during the emission period t4, when the fifth transistor T5 turns on, the sixth transistor T6 is turned off, thereby floating one end of the second capacitor C2. As a result, the second capacitor C2, in addition to holding the threshold voltage Vth during the sampling and programming periods t2 and t3, does not participate in the voltage of the emission nodes, the first node N1 and the fourth node N4, during the emission period t4. That is, during the emission period t4, voltage coupling between the second capacitor C2 and the first node N1 may be removed or minimized. Therefore, emission delay, luminance distortion, or degradation in display quality caused by voltage coupling during the emission period t4 may be prevented.

Additionally, in the aforementioned embodiment, the second capacitor C2 is supplied with the reference voltage Vref through the sixth transistor T6. That is, during the compensation operation of the second capacitor C2, the voltage at one electrode of the second capacitor C2 may be fixed to a DC voltage and stabilized through the sixth transistor T6. Furthermore, since a separate circuit element (e.g., a transistor) and signal wiring for supplying the voltage to the second capacitor C2 are not required, the size and complexity of the circuit are reduced, and power consumption may be decreased.

The skip period SP may include an anode initialization period t5 and an emission period t6.

During the anode initialization period t5, the first emission signal EM1 is switched to a high level, turning off the fourth transistor T4 and turning on the third transistor T3. When the anode reset voltage VAR is applied to the fourth node N4 through the turned-on third transistor T3, the anode electrode of the light-emission element LD may be initialized to the anode reset voltage VAR.

During the anode initialization period t5, the light-emitting element LD does not emit light due to the anode reset voltage VAR applied to its anode electrode. Instead, the first capacitor C1 may maintain the voltage at the gate electrode of the driving transistor DT at the voltage programmed in the previous refresh period RP.

Meanwhile, during the anode initialization period t5, as the anode reset voltage VAR is directly applied to the anode electrode of the light-emitting element LD, the anode electrode voltage may discharge at a relatively fast rate, improving the discharge delay of the light-emitting element LD. Through this anode initialization, luminance integration deviations according to the refresh rate do not occur, and flicker caused by differences in luminance integration may be suppressed.

During the emission period t6, the first emission signal EM1 is switched to a low level, turning on the fourth transistor T4 and turning off the third transistor T3. During the emission period t6, the light-emitting element LD may emit light at a luminance corresponding to the voltage programmed in the previous refresh period RP.

In the above driving method, when the first scan signals SC11 and SC12 switch from a high-level, i.e., turn-on level to a low-level, i.e., turn-off level, the voltage of the second node N2, which is the gate electrode of the driving transistor DT, may experience a kick-back due to coupling between the second node N2 and the first scan lines GL11 and GL12. Accordingly, the voltage Vdata-Vth stored in the first capacitor C1 may be reduced when the first scan signals SC11 and SC12 switch. This kick-back phenomenon may be exacerbated when the first transistor T1 is configured as a dual-gate transistor and receives two first scan signals SC11 and SC12 through two scan lines GL11 and GL12. Due to the kick-back phenomenon, the luminance of the light-emitting element LD during the emission periods t4 and t6 may be somewhat lower than the luminance required based on the actually applied data voltage Vdata.

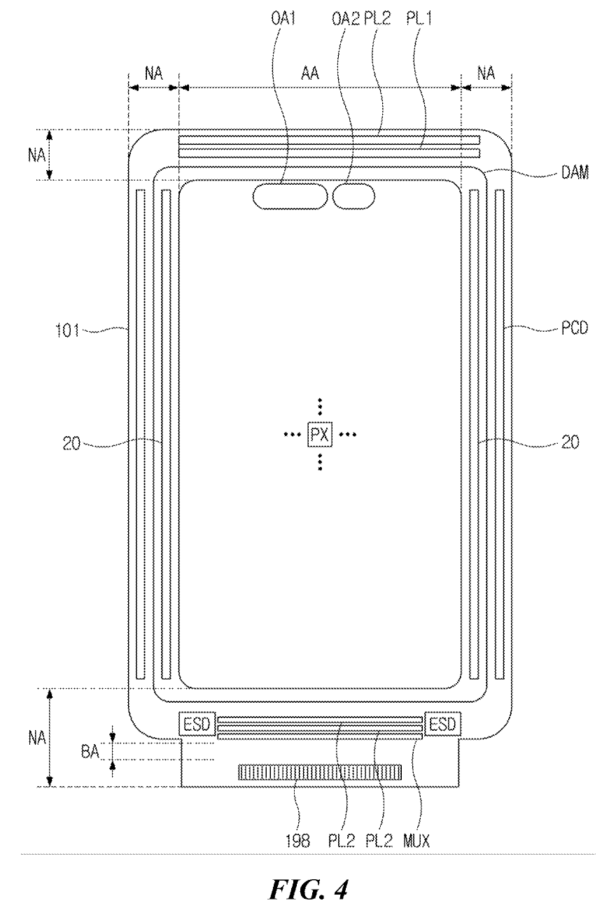

FIG. 4 is a plan view illustrating the configuration of a display panel according to an embodiment.

Referring to FIG. 4, the display device 1 may include driving circuits for generating various signals or driving a plurality of pixels PX in the display area AA. Some of the driving circuits may be included on the display panel 50. The driving circuits for controlling (or driving) the pixels PX may include a gate driver 20, data lines, a multiplexer MUX, an electrostatic discharge ESD circuit, a high-potential driving voltage line PL1, a low-potential driving voltage line PL2, and an inverter circuit.

The display device 1 may further include additional elements for driving the pixels PX. These additional elements may include circuits for providing functions such as touch detection, user authentication (e.g., fingerprint recognition), multi-level pressure detection, and tactile feedback. The additional elements may be arranged in the non-display area NA or in an external circuit connected to the non-display area NA through connection wiring.

The display panel 50 may include a substrate 101, and the substrate 101 may include a display area (active area, AA) and a non-display area (non-active area, NA). The display area AA of the substrate 101 may be the area where a plurality of pixels PX are arranged and images are displayed. The non-display area NA of the substrate 101 may be the area where images are not displayed. For example, the non-display area NA may be the bezel area, but is not limited to this term. The non-display area NA may be adjacent to the display area AA and placed outward of the display area AA. Alternatively, the non-display area NA may be arranged to surround the entire or part of the display area AA. Additionally, the non-display area NA may also be the area where a plurality of pixels PX are not arranged, but it is not limited to this.

In FIG. 4, the non-display area NA is shown surrounding the rectangular display area AA; however, the shape and arrangement of the display area AA and the adjacent non-display area NA are not limited to the illustration. The display area AA and non-display area NA may have shapes suitable for the design of an electronic device equipped with the display device 1. In the case of display devices for wearable devices, such as wristwatches, the display area AA and non-display area NA may have a circular shape, and the concepts of these embodiments may also be applied to free-form display devices, such as those used in vehicle dashboards. Exemplary shapes of the display area AA may include a pentagon, hexagon, octagon, circle, ellipse, or the like, but are not limited thereto.

A bending area BA may be provided in a portion of the non-display area NA. The bending area BA may be located between the display area AA and the pad section 198 in the non-display area NA. Additionally, the bending area BA may be the area where the connection wiring is formed.

The bending area BA may be a region where a portion of the substrate 101 is bent to place the pad portion and an external module bonded to the pad portion 198 on the back side of the substrate 101. For example, as the bending area BA is bent toward the back side of the substrate 101, the external module bonded to the pad section 198 may move to the back side of the substrate 101, and the external module may not be visible when viewed from the top of the substrate 101. Furthermore, as the bending area BA is bent, the size of the non-display area NA visible from the top of the substrate 101 may decrease, enabling the implementation of a narrow bezel. In FIG. 4, the non-display area NA is shown to have a bending area BA, but this is not limited to the illustration. For example, the bending area BA may be located in the display area AA, and since the display area AA itself may be bent in various directions, the bending area BA located in the display area AA may also have the effects mentioned in the present disclosure.

A pad portion 198 is disposed on one side of the non-display area NA. The pad portion 198 is a metal pattern to which external modules, such as a flexible printed circuit board (FPCB) or chip-on-film (COF), are bonded. Although the pad portion 198 is shown to be disposed on one side of the substrate 101, the form and placement of the pad portion 198 are not limited thereto.

A gate driver 20, which provides gate signals to the thin-film transistors, may be disposed on the other side of the non-display area NA. The gate driver 20 includes various gate driving circuits, which may be directly formed on the substrate 101. In this case, the gate driver 20 may be a gate-in-panel (GIP).

The gate driver 20 may be disposed between a dam DAM in the non-display area NA and the display area AA of the substrate 101.

The high-potential driving voltage line PL1, low-potential driving voltage line PL2, multiplexer MUX, electrostatic discharge circuit ESD, and a plurality of connection wiring portions may be arranged between the display area AA and the pad portion 198 in the non-display area NA.

The high-potential driving voltage line PL1, low-potential driving voltage line PL2, multiplexer MUX, and electrostatic discharge circuit ESD may be arranged between the display area AA and the bending area BA.

The connection wiring portions may be arranged in the non-display area NA. For example, the connection wiring portions may be arranged in the bending area BA of the non-display area NA, where the substrate is bent. The connection wiring portion may be configured to deliver signals (voltages) from an external module bonded to the pad portion 198 to a circuit portion such as the display area AA or the gate driver 20. For example, various signals, such as signals for driving the gate driver 20, data signals, high-potential driving voltage, and low-potential driving voltage, may be transmitted through the connection wiring portion.

A dam DAM may be arranged in the non-display area NA to surround all or part of the display area AA. The dam DAM may be adjacent to the display area AA and disposed outward of the display area AA.

The dam DAM may be arranged along the periphery of the display area AA to control the flow of an organic layer, which is the material of the second encapsulation layer in the encapsulation layer to be described later, disposed on the light-emitting element layer. The number of dams DAM may be configured as one or more.

The dam DAM may be arranged between the display area AA and the high-potential driving voltage line PL1, low-potential driving voltage line PL2, multiplexer MUX, or electrostatic discharge circuit ESD.

A panel crack detector (PCD) may further be arranged in a portion of the non-display area NA of the substrate 101.

The panel crack detector PCD may be arranged between the edge (or end) of the substrate 101 and the dam DAM. Alternatively, the panel crack detector PCD may be arranged below the dam DAM and at least partially overlap with the dam DAM.

The display panel 50 may have one or more optical areas OAs arranged. One or more optical areas OAs may be arranged in overlap with one or more optoelectronic devices, such as an imaging device like a camera (image sensor), or sensing devices such as a proximity sensor or an illuminance sensor.

For the operation of optoelectronic devices, one or more optical areas OA1, OA2 may include a light-transmitting structure and have a transmission rate above a certain level. For example, at least some OA1 of the optical areas OA1 and OA2 may have a light-transmissive structure configured by patterning the cathode electrode in regions where pixels PX are not arranged. The cathode electrode may be patterned either by laser removal or by selective formation using a cathode deposition prevention layer. In this embodiment, the wirings (e.g., scan lines GL) may extend across the optical area OA1 and be arranged to bypass the region where the cathode electrode is removed.

At least some of the optical areas OA1 and OA2 may have a hole-in-display (HID) or hole-in-active-area (HiAA) structure. For example, optical area OA2 may be implemented by forming a hole that penetrates the entire panel. In this embodiment, the wirings (e.g., scan lines GL) may be arranged to bypass the optical area OA2.

Alternatively, the light-transmissive structure may be formed by separating the light-emitting element within the pixel PX. In this embodiment, the light-emitting element of the pixel PX is located in the optical areas OA1 and OA2, and the multiple transistors constituting the pixel PX are arranged around the optical areas OA1 and OA2, with the light-emitting element and the pixel being electrically connected through a transparent metal layer.

The number of pixels PX per unit area in one or more optical areas OA1 and OA2 may be smaller than the number of pixels PX per unit area in the remaining area excluding the optical areas OA1 and OA2. That is, the resolution of the one or more optical areas OA1 and OA2 may be lower than the resolution of the remaining area.

Hereinafter, the structure of the display device 1 is described based on the optical area OA2 having a hole-in-display or hole-in-active-area structure. The region overlapping with the optical area OA2 in the row direction (i.e., the region arranged parallel to the optical area OA2 in the row direction) is referred to as the first region, and the region in the row direction that does not overlap with the optical area OA2 is referred to as the second region. Here, the first region may refer to the first pixels arranged in the first region, and the second region may refer to the second pixels arranged in the second region.

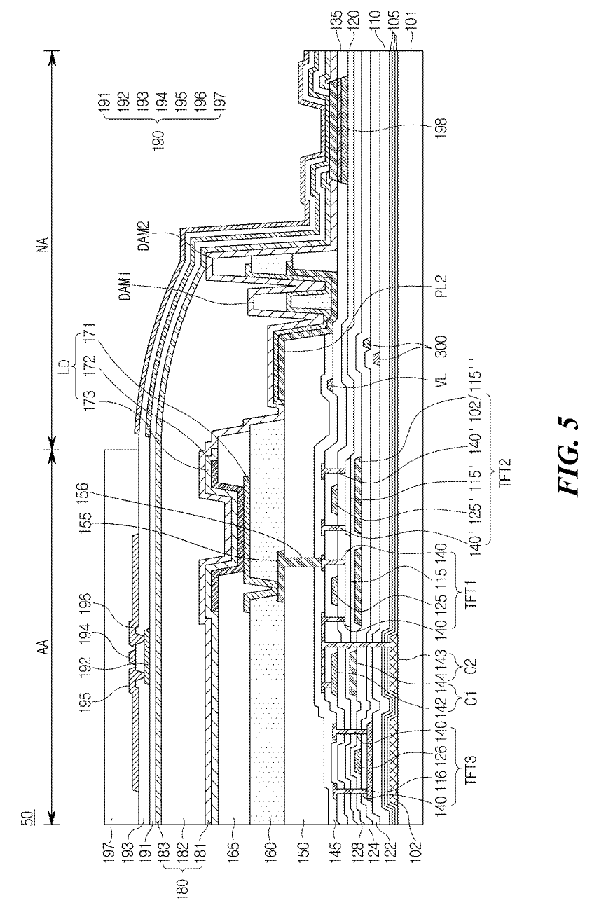

FIG. 5 is a schematic cross-sectional of a display panel according to an embodiment.

Referring to FIG. 5, the display panel 50 includes a display area AA, where pixels PX are located, and a non-display area NA, which is arranged to surround the display area AA and accommodates the gate driver 20 (FIG. 1) and the data driver 30 (FIG. 1). The display panel 50 includes a substrate 101, thin-film transistors TFT1, TFT2 and TFT3, a bank layer 165, a light-emitting element LD, an encapsulation layer 180, a touch layer 190, a touch protective film 197, dams DAM1 and DAM2, and a pad portion 198.

The substrate 101 supports various components of the display panel 50. The substrate 101 may be formed of a transparent dielectric material such as glass, plastic, and the like. In the case of being made of plastic, the substrate 101 may be referred to as a plastic film or a plastic substrate. For example, the substrate 101 may be in the form of a film and include one of a polyimide-based polymer, a polyester-based polymer, a silicone-based polymer, an acrylic-based polymer, a polyolefin-based polymer, and their copolymers, but the embodiments of this specification are not limited to thereto. Additionally, when made of plastic, the substrate 101 may be formed in a double structure. For example, the substrate may be a double structure with an adhesive layer between the first polyimide layer and the second polyimide layer.

When made of glass, the substrate 101 may be referred to as a glass substrate. For example, the glass substrate may include a shielding metal 102 under the thin-film transistors TFT1, TFT2, and TFT3 to protect against external light or signal interference.

Thin-film transistors TFT1, TFT2, and TFT3 for driving the light-emitting element LD may be arranged on the substrate 101 in the display area AA. The thin-film transistors TFT1, TFT2, and TFT3 drive the light-emitting element LD in the display area AA.

For the convenience of explanation, FIG. 5 shows only the driving transistor TFT1 (the driving transistor DT in FIG. 2), and two switching transistors TFT2 and TFT3 (the first transistor T1 and the fourth transistor T4 in FIG. 2) among the various thin-film transistors that may be included in the display device 1, but the thin-film transistors TFT1, TFT2, and TFT3 are not limited thereto. Hereinafter, an example where the thin-film transistors TFT1, TFT2, and TFT3 have a coplanar structure will be described, but the thin-film transistors TFT1, TFT2, and TFT3 may also be implemented in other various structures, such as a staggered structure.

The third thin-film transistor TFT3 may include a semiconductor layer 116, a gate electrode 126, and source and drain electrodes 140. The semiconductor layer 116 may be made of polysilicon (p-Si), and in this case, a certain region may be doped with impurities. Additionally, the semiconductor layer 116 may be composed of amorphous silicon (a-Si) or various organic semiconductor materials such as pentacene. The semiconductor layer 116 may be made of oxide. The embodiments of the present specification are not limited to the material constituting the semiconductor layer 116. The semiconductor layer 116 may be an active layer, but the term is not limited thereto.

The gate electrode 126 may be arranged on top of the semiconductor layer 116. The gate electrode 126 may be made of various conductive materials, such as magnesium (Mg), aluminum (Al), nickel (Ni), chromium (Cr), molybdenum (Mo), tungsten (W), gold (Au), or their alloys, but the embodiments of this specification are not limited thereto.

The gate insulating layer 122 may be arranged between the semiconductor layer 116 and the gate electrode 126. The gate insulating layer 122 may be a layer for insulating the semiconductor layer 116 and the gate electrode 126 and may be made of an insulating material. For example, the gate insulating layer 122 may be composed of a single layer or multilayer of silicon oxide (SiOx) or silicon nitride (SiNx), but is not limited thereto.

The source and drain electrodes 140 are electrically connected to the semiconductor layer 116 and spaced apart from each other, and may be made of a conductive material such as copper (Cu), aluminum (Al), molybdenum (Mo), titanium (Ti), or their alloys, but are not limited thereto.

A buffer layer 105, shielding metal 102, and first insulating layer 110 may be arranged between the semiconductor layer 116 and the substrate 101. The buffer layer 105 may delay the diffusion of moisture and/or oxygen that has penetrated the substrate 101. The first insulating layer 110 protects the semiconductor layer 115 and may block various types of defects entering from the substrate 101. The shielding metal 102 may be disposed between the buffer layer 105 and the first insulating layer 110 and overlap with the semiconductor layer 116 to protect the third thin-film transistor TFT3 from external light or signal interference.

The topmost layer of the buffer layer 105 in contact with the first insulating layer 110 may be formed of a material with different etching characteristics compared to the other layers of the buffer layer 105, the first insulating layer 110, the second insulating layer 120, and the third insulating layer 135. The topmost layer of the buffer layer 105 in contact with the first insulating layer 110 may be formed of either silicon nitride (SiNx) or silicon oxide (SiOx). The other layers of the buffer layer 105, the first insulating layer 110, the second insulating layer 120, and the third insulating layer 135 may be formed of the remaining material, either silicon nitride (SiNx) or silicon oxide (SiOx). For example, the topmost layer of the buffer layer 105 in contact with the first insulating layer 110 may be formed of silicon nitride (SiNx), and the other layers of the buffer layer 105, the first insulating layer 110, the second insulating layer 120, and the third insulating layer 135 may be formed of silicon oxide (SiOx), but they are not limited thereto.

The first thin-film transistor TFT1 and the second thin-film transistor TFT2 may each include a semiconductor layer 115, 115′, a gate electrode 125, 125′, and source and drain electrodes 140, 140′. A second insulating layer 120, also referred to as a gate insulating layer, may be disposed between the semiconductor layer 115, 115′ and the gate electrode 125, 125′.

An interlayer insulating layer 128 may be disposed between the first thin-film transistor TFT1, the second thin-film transistor TFT2, and the third transistor TFT3. For example, as shown in FIG. 5, the semiconductor layer 115, 115′ of the first thin-film transistor TFT1 and the second thin-film transistor TFT2 are disposed above the interlayer insulating layer 128, while the semiconductor layer 116 of the third transistor TFT3 is disposed below the third transistor TFT3.

The first thin-film transistor TFT1 may include a semiconductor layer 115 arranged on the interlayer insulating layer 128, a gate electrode 125 overlapping the semiconductor layer 115 through the second insulating layer 120, and source and drain electrodes 140 formed on the third insulating layer 135 and in contact with the semiconductor layer 115.

The semiconductor layer 115 may be the region where a channel is formed during the operation of the first thin-film transistor TFT1. The semiconductor layer 115 may be formed of an oxide semiconductor, and may also be formed of various organic semiconductors such as amorphous silicon (a-Si), polycrystalline silicon (poly-Si), or pentacene, but is not limited to these materials. The semiconductor layer 115 may be formed on the interlayer insulating layer 128. The semiconductor layer 115 may include a channel region, a source region, and a drain region. The channel region may be formed by overlapping the gate electrode 125 with the channel region of the semiconductor layer 115 through the second insulating layer 120, thereby forming a channel between the source and drain regions. The source region may be electrically connected to the source electrode 140 through a contact hole that penetrates the second insulating layer 120 and the third insulating layer 135. The drain region may be electrically connected to the drain electrode 140 through a contact hole that penetrates the second insulating layer 120 and the third insulating layer 135.

The gate electrode 125 may be formed on the second insulating layer 120 and may overlap the channel region of the semiconductor layer 115 through the second insulating layer 120. The gate electrode 125 may be formed of a first conductive material, which is a single layer or multilayer of one of magnesium (Mg), molybdenum (Mo), aluminum (Al), chromium (Cr), gold (Au), titanium (Ti), nickel (Ni), neodymium (Nd), or copper (Cu), or their alloys, but is not limited to these materials.

The source electrode 140 may be connected to the exposed source region of the semiconductor layer 115 through a contact hole that penetrates the second insulating layer 120 and the third insulating layer 135. The drain electrode 140 may be opposite to the source electrode 140 and may be connected to the drain region of the semiconductor layer 115 through a contact hole that penetrates the second insulating layer 120 and the third insulating layer 135. These source and drain electrodes 140 may be formed of a second conductive material, which is a single layer or multilayer of one or more of molybdenum (Mo), aluminum (Al), chromium (Cr), gold (Au), titanium (Ti), nickel (Ni), neodymium (Nd), or copper (Cu), or their alloys, but is not limited to these materials.

The second thin-film transistor TFT2 may include a semiconductor layer 115′ disposed on the interlayer insulating layer 128, a gate electrode 125′ overlapping with the semiconductor layer 115′ with the second insulating layer 120 in between, and source and drain electrodes 140′ formed on the third insulating layer 135, which are in contact with the semiconductor layer 115′.

The semiconductor layer 115′ may be the region where a channel is formed during the operation of the second thin-film transistor TFT2. The semiconductor layer 115′ may be formed of an oxide semiconductor, and may also be formed from various organic semiconductors such as amorphous silicon (a-Si), polycrystalline silicon (poly-Si), or pentacene, without being limited to these materials. The semiconductor layer 115′ may be formed on the interlayer insulating layer 128. The semiconductor layer 115′ may include a channel region, a source region, and a drain region. The channel region may overlap with the gate electrode 125′ through the second insulating layer 120, forming a channel between the source and drain regions. The source region may be electrically connected to the source electrode 140′ through a contact hole that penetrates the second insulating layer 120 and the third insulating layer 135. The drain region may be electrically connected to the drain electrode 140′ through a contact hole that penetrates the second insulating layer 120 and the third insulating layer 135.

A shielding metal 102 may be disposed between the interlayer insulating layer 128 and the interlayer insulating layer 124 to protect the second thin-film transistor TFT2 from external light or signal interference.

The gate electrode 125′ may be formed on the second insulating layer 120 and may overlap the channel region of the semiconductor layer 115′ through the second insulating layer 120. The gate electrode 125′ may be made of a first conductive material in the form of a single layer or multilayer, and may be formed from one or more of magnesium (Mg), molybdenum (Mo), aluminum (Al), chromium (Cr), gold (Au), titanium (Ti), nickel (Ni), neodymium (Nd), or copper (Cu), without being limited to these materials.

The source electrode 140′ may be connected to the source region of the semiconductor layer 115′ through the contact hole that passes through the second insulating layer 120 and the third insulating layer 135. The drain electrode 140′ may be opposite to the source electrode 140′ and may be connected to the drain region of the semiconductor layer 115′ through the contact hole that passes through the second insulating layer 120 and the third insulating layer 135. The source and drain electrodes 140′ may be formed from a second conductive material, which may be made of a single layer or multilayer structure using one or more of molybdenum (Mo), aluminum (Al), chromium (Cr), gold (Au), titanium (Ti), nickel (Ni), neodymium (Nd), or copper (Cu), or alloys of these materials, without being limited to these materials.

In one embodiment, the shielding metal 102, which is disposed beneath the semiconductor layer 115′ of the second transistor TFT2, may function as the gate electrode 115′′ of the second transistor TFT2. The second transistor TFT2 may be formed in a dual-gate (or double-gate) structure, which includes a first gate electrode 125′ (top gate electrode) disposed above the semiconductor layer 115′, and a second gate electrode 115′′ (bottom gate electrode) disposed beneath the semiconductor layer 115′. In one embodiment, the top gate electrode 125′ may be made of a low-resistance material such as aluminum (Al), while the bottom gate electrode 115′′ may be made of a high-resistance material such as molybdenum (Mo). However, the embodiment is not limited thereto.

A capacitor Cst may be further disposed on the substrate 101. The capacitor Cst may be a storage capacitor C1 (FIG. 2) or a compensation capacitor C2 (FIG. 2). For convenience of explanation, FIG. 5 illustrates the storage capacitor C1 as an example. The capacitor Cst may be configured to include a first electrode 143, a second electrode 144, and a third electrode 142.

At least one insulating layer may be disposed between the first electrode 143 and the second electrode 144, and at least one insulating layer may be disposed between the second electrode 144 and the third electrode 142. At least one of the first electrode 143, second electrode 144, and third electrode 142 may be connected to the source electrode 140(140′) or drain electrode 140(140′) of the thin-film transistors TFT1, TFT2, or TFT3.

A connection electrode 155 may be disposed between the first intermediate layer 150 and the second intermediate layer 160. The connection electrode 155 may be exposed through a connection electrode contact hole 156 passing through the protective layer 145 and the first intermediate layer 150 and may be connected to the drain electrode 140. The connection electrode 155 may be made of a material with low resistivity, similar or identical to the drain electrode 140, but is not limited thereto.

A light-emitting element LD including a light-emitting layer 172 may be disposed on the second intermediate layer 160 and the bank layer 165. The light-emitting element LD may include an anode electrode 171, at least one light-emitting layer 172 formed on the anode electrode 171, and a cathode electrode 173 formed on the light-emitting layer 172.

The anode electrode 171 may be disposed on the first intermediate layer 150 through a contact hole passing through the second intermediate layer 160 and may be electrically connected to the connection electrode 155 exposed on the upper surface of the second intermediate layer 160.

The anode electrode 171 of each pixel may be formed to be exposed by the bank layer 165. The bank layer 165 may be formed of an opaque material (e.g., black) to prevent light interference between adjacent pixels. In this case, the bank layer 165 may include a light-blocking material made of at least one of color pigments, organic black, and carbon, but is not limited thereto.

At least one light-emitting layer 172 may be formed on the anode electrode 171 in the light-emitting region defined by the bank layer 165. At least one light-emitting layer 172 may include a hole transport layer, a hole injection layer, a hole blocking layer, the light-emitting layer 172, an electron injection layer, an electron blocking layer, and an electron transport layer, and may be sequentially or reversely stacked depending on the emission direction. Additionally, the light-emitting layer 172 may have a first and a second light-emitting stack facing each other with a charge generation layer therebetween. In this case, one of the light-emitting layers 172 in the first or second light-emitting stacks may generate blue light, and the remaining light-emitting layer 172 may generate yellow-green light, such that white light is generated through the first and second light-emitting stacks. The white light generated in the light-emitting stack may be incident on a color filter located above or below the light-emitting layer 172, allowing for the implementation of color images. Alternatively, without a separate color filter, color light corresponding to each pixel may be generated from each light-emitting layer 172 to implement color images. For example, the light-emitting layer 172 of a red pixel may generate red light, the light-emitting layer 172 of a green pixel may generate green light, and the light-emitting layer 172 of a blue pixel may generate blue light.

The cathode electrode 173 may be formed to face the anode electrode 171 with the light-emitting layer 172 in between and may receive a low-potential drive voltage ELVSS.

The encapsulation layer 180 may block external moisture or oxygen from penetrating, protecting the light-emitting element LD, which is vulnerable to external moisture or oxygen. To achieve this, the encapsulation layer 180 may include at least one inorganic encapsulation layer and at least one organic encapsulation layer, but this is not limited thereto. Hereinafter, the structure of the encapsulation layer 180, where the first encapsulation layer 181, the second encapsulation layer 182, and the third encapsulation layer 183 are sequentially stacked, will be explained as an example.

The first encapsulation layer 181 is formed on the substrate 101 where the cathode electrode 173 is formed. The third encapsulation layer 183 is formed on the substrate 101 where the second encapsulation layer 182 is formed, and may be configured, along with the first encapsulation layer 181, to surround the top surface, bottom surface, and side surfaces of the second encapsulation layer 182. The first encapsulation layer 181 and the third encapsulation layer 183 may minimize or prevent the penetration of external moisture or oxygen into the light-emitting element LD. The first encapsulation layer 181 and the third encapsulation layer 183 may be formed of inorganic insulating materials, such as silicon nitride (SiNx), silicon oxide (SiOx), silicon oxynitride (SiON), or aluminum oxide (Al₂O₃), which may be deposited at low temperatures. Since the first encapsulation layer 181 and the third encapsulation layer 183 are deposited in a low-temperature atmosphere, they may prevent damage to the light-emitting element LD, which is vulnerable to high temperatures during the deposition process of the first and third encapsulation layers 181 and 183.

The second encapsulation layer 182 may serve as a buffer to alleviate stress between layers due to the bending of the display device 1 (FIG. 1), and may flatten the step differences between the layers. The second encapsulation layer 182 may be formed on the substrate 101, where the first encapsulation layer 181 is formed, using non-photosensitive organic insulating materials such as acrylic resin, epoxy resin, phenolic resin, polyamide resin, polyimide resin, polyethylene, or silicon oxycarbide (SiOC), or photosensitive organic insulating materials such as photoacrylic, but is not limited to these materials. When the second encapsulation layer 182 is formed by an inkjet method, dams DAM1 and DAM2 may be placed to prevent the liquid form of the second encapsulation layer 182 from diffusing to the edge of the substrate 101. The dams DAM1 and DAM2 may be placed closer to the edge of the substrate 101 than the second encapsulation layer 182. Through these dams DAM1 and DAM2, diffusion of the second encapsulation layer 182 into the pad area, where the conductive pads are placed at the outermost edge of the substrate 101, may be prevented.

The dams DAM1 and DAM2 are designed to prevent the diffusion of the second encapsulation layer 182. However, if the second encapsulation layer 182 exceeds the height of the dams DAM1 and DAM2 during the process, the organic second encapsulation layer 182 may be exposed to the outside, allowing moisture or other elements to easily penetrate into the light-emitting device. Therefore, to prevent this, the dams DAM1 and DAM2 may be formed with at least two layers. The dams DAM1 and DAM2 may be provided in two or more layers. In this case, the two or more dams DAM1 and DAM2 may be formed with the same or different structures.

The dams DAM1 and DAM2 may be placed on an interlayer insulating layer disposed on the third insulating layer 135 in the non-display area NA. The embodiments in this specification are not limited to this, and the interlayer insulating layer may be the third insulating layer 135.

The first dam DAM1 may be formed simultaneously with the second intermediate layer 160 and the bank layer 165. When the second intermediate layer 160 is formed, the lower layer of the first dam DAM1 is formed together, and when the bank layer 165 is formed, the upper layer of the first dam DAM1 is formed together, resulting in a double-layer structure that is stacked and formed.

In the first dam DAM1, a metal layer of the same material as the anode electrode 171 may be arranged between the upper and lower layers, and beneath the lower layer, a metal layer of the same material as the source and drain electrodes 140 of the thin-film transistors TFT1, TFT2, and TFT3, and a metal layer of the same material as the connection electrode 155 may be arranged in contact with each other.

The second dam DAM2 may be formed simultaneously with the first intermediate layer 150, the second intermediate layer 160, and the bank layer 165. When the first intermediate layer 150 is formed, the lower layer of the second dam DAM2 is formed together, when the second intermediate layer 160 is formed, the lower layer of the first dam DAM1 and the middle layer of the second dam DAM2 are formed together, and when the bank layer 165 is formed, the upper layer of dams DMA1 and DAM2 are formed together, resulting in a triple-layer stacked structure.

In the second dam DAM2, a metal layer of the same material as the anode electrode 171 may be arranged between the upper and middle layers, a metal layer of the same material as the connection electrode 155 may be arranged between the middle and lower layers, and beneath the lower layer, a metal layer of the same material as the source and drain electrodes 140 of the thin-film transistors TFT1, TFT2, and TFT3 may be arranged.

Therefore, the dams DAM1 and DAM2 may be composed of the same material as the first intermediate layer 150, the second intermediate layer 160, and the bank layer 165, but are not limited thereto. Additionally, there may be at least one insulating layer, including an interlayer insulating layer 128, arranged below the first intermediate layer 150.

The dams DAM1 and DAM2 may be formed overlapping with the low-potential driving voltage line PL2. For example, in the non-display area NA, the dams DAM1 and DAM2 may have the low-potential driving voltage line PL2 formed in the lower layers of the region where they are located.

The low-potential driving voltage line PL2 and the gate driving unit 20 configured in a GIP (Gate In Panel) form are formed around the outer edges of the display panel, with the low-potential driving voltage line PL2 being positioned outside the gate driving unit 20. This low-potential driving voltage line PL2 may be connected to the cathode electrode 173 and may serve as the low-potential driving voltage ELVSS, as shown in FIG. 1.

The low-potential driving voltage line PL2 may be placed on the same layer as the connection electrode 155 on the first intermediate layer 150. Alternatively, the low-potential driving voltage line PL2 may be arranged in the same layer as the source and drain electrodes 140 of the first thin-film transistor TFT1 on the third insulating layer 135, or may be arranged in the same layer as the gate electrode 125 of the thin-film transistor TFT1 on the second insulating layer 120. However, the embodiments are not limited to these configurations.

At least one power line VL may be placed between the gate driving unit 20 and the display area AA. At least one power line VL may be arranged in the same layer as the source and drain electrodes 140 of the third thin-film transistor TFT3. Of course, it is not limited thereto. Although it is simply expressed in the drawing, at least one power line VL, consisting of the anode reset voltage line VARL (FIG. 1) and the reference voltage line VrefL, may be arranged side by side in the same layer. Alternatively, the anode reset voltage line VARL (FIG. 1) and the reference voltage line VrefL may be arranged side by side or overlapping in different layers. At least one power line VL is shown as being placed between the gate driving unit 20 and the display area AA, but the embodiments are not limited thereto.

On the encapsulation layer 180, a touch layer 190 may be placed. In the touch layer 190, the touch buffer layer 191 may be positioned between the touch sensor metal and the cathode electrode 173 of the light-emitting device LD, the touch sensor metal includes the touch electrode connection lines 192 and 194 and the touch electrodes 195 and 196.

The touch buffer layer 191 may block the penetration of chemicals (such as developer or etching solution) or moisture from the outside, which may contain organic materials, into the light-emitting layer 172. As a result, the touch buffer layer 191 may prevent damage to the light-emitting layer 172, which is vulnerable to chemicals or moisture.

The touch buffer layer 191 is formed from an organic insulating material having a low dielectric constant of 1-3, and may be formed at a low temperature (e.g., below 100°C) to prevent damage to the light-emitting layer 172, which contains organic material and is sensitive to high temperatures. For example, the touch buffer layer 191 may be made of acrylic-based, epoxy-based, or siloxane-based materials. The touch buffer layer 191, which has flattening performance with an organic insulating material, may prevent damage to the encapsulation layer 180 due to the bending of the organic light-emitting display device and the breaking of the touch sensor metal formed on the touch buffer layer 191.

According to a mutual-capacitance-based touch sensor structure, the touch electrodes 195 and 196 are arranged on the touch buffer layer 191, and the touch electrodes 195 and 196 may be arranged to cross each other.

The touch electrode connection lines 192 and 194 may electrically connect the touch electrodes 195 and 196. The touch electrode connection lines 192 and 194 and the touch electrodes 195 and 196 may be positioned in different layers, separated by the touch insulating layer 193.

The touch electrode connection lines 192 and 194 are arranged to overlap the bank layer 165, which can prevent a reduction in aperture ratio.

Meanwhile, the touch electrodes 195 and 196 may be electrically connected to the touch driving circuit (not shown) through the touch pad 198, with part of the touch electrode connection line 192 passing through the upper and side portions of the encapsulation layer 180 and the upper and side portions of the dam DAM1 and DAM2.

Part of the touch electrode connection line 192 may receive a touch drive signal from the touch driving circuit and deliver it to the touch electrodes 195 and 196, while also transmitting the touch sensing signals from the touch electrodes 195 and 196 to the touch driving circuit.

The touch electrode connection line 192 may be composed of double wiring, with each layer of the touch electrode connection line 192 being formed on the touch buffer layer 191 and the touch insulating layer 193, respectively.

A touch protective layer 197 may be disposed on the touch electrodes 195 and 196. Although the touch protective layer 197 is shown in the drawing as being disposed only on the touch electrodes 195 and 196, this is not limited to that, and the touch protective layer 197 may extend to before or after the dam DAM1 and DAM2, and may also be disposed on the touch electrode connection lines 192 and 194.

The touch pad may be configured to include a first pad layer made of the same material as the gate electrode 126, a second pad layer made of the same material as the source and drain electrodes 140, and a third pad layer made of the same material as the touch electrodes 195 and 196 or the touch electrode connection lines 192 and 194.

Furthermore, a color filter (not shown) may be additionally disposed on the encapsulation layer 180, and the color filter may be positioned on the touch layer 190 or between the encapsulation layer 180 and the touch layer 190.

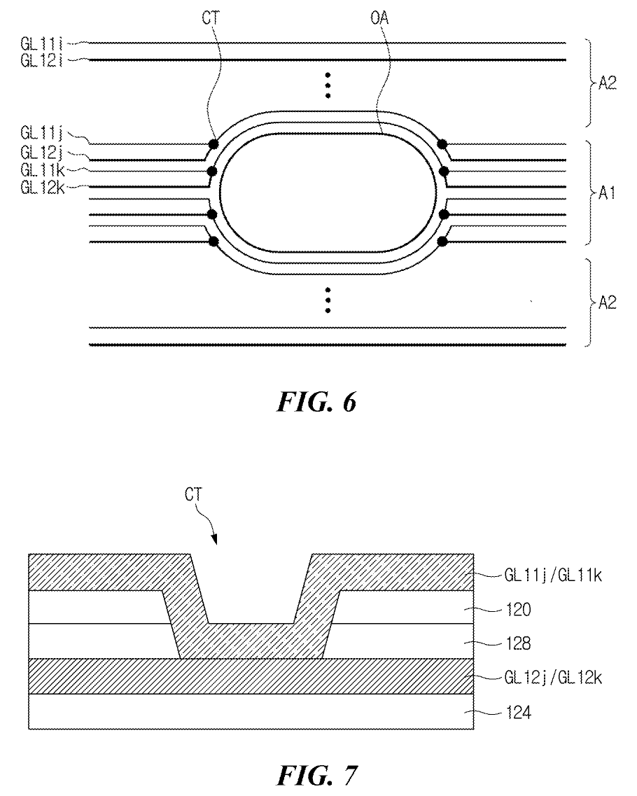

FIG. 6 is an enlarged plan view of the optical region of FIG. 4, schematically showing the scan lines around the optical region. FIG. 7 is a schematic cross-sectional view of the contact hole area of FIG. 6.

As described with reference to FIG. 4, a gate driving unit 20 may be disposed on both sides of the display area AA. Scan lines GL11i, GL12i, GL11j, GL12j, GL11k, GL12k may extend across the display area AA from the gate driving unit 20 and may be connected to the pixels PX disposed in the display area AA. In FIG. 6, the first scan lines GL11i, GL12i, GL11j, GL12j, GL11k, GL12k connected to the first transistor T1 in FIG. 2 are shown as representative. Specifically, the scan lines GL11i, GL12i, GL11j, GL12j, GL11k, and GL12k are connected to the first transistor T1 of the pixels arranged in the i-th, j-th, and k-th pixel rows. The scan lines GL11i, GL12i, GL11j, GL12j, GL11k, and GL12k connected to each pixel row may include the first scan line GL11i, GL11j, and GL11k connected to the top gate electrode 125′ of the first transistor T1 and the second scan lines GL12i, GL12j, and GL12k connected to the bottom gate electrode 115′′.

In the second region A2, where the optical area OA is not formed, the scan lines GL11i and GL12i may extend parallel to each other in the row direction across the display area AA.

In the first region A1, where the optical area OA is formed, the scan lines GL11j, GL12j, GL11k, and GL12k may extend along the outer circumference of the optical area OA around its perimeter. As shown in the drawing, when the optical area OA is formed in a circular or elliptical shape, the scan lines GL11j, GL12j, GL11k, and GL12k may extend in a curved manner following the shape of the optical area OA.

In one embodiment, the first-first scan lines GL11j and GL11k extend in a curve along the outer circumference of the optical area OA. On the other hand, the first-second scan lines GL12j and GL12k may be separated into two regions on either side of the optical area OA. Referring to FIG. 7, the separated first-second scan lines GL12j and GL12k may be electrically connected to the first-first scan lines GL11j and GL11k through contact holes CT passing through the insulating layers 128 and 120 on both sides of the optical area OA. That is, the separated first-second scan lines GL12j and GL12k may be electrically connected to the first-first scan lines GL11j and GL11k around the optical area OA. In this embodiment, the first-first scan lines GL11j and GL11k may function as jumping lines between the separated first-second scan lines GL12j and GL12k.

In one embodiment, the first-first scan lines GL11i, GL11j, and GL11k may be made of a low-resistance material, and the first-second scan lines GL12i, GL12j, and GL12k may be made of a high-resistance material.

In one embodiment, the first-first scan lines GL11i, GL11j, and GL11k are driven by a dual feeding method that receives scan signals SC11 from two gate drivers 20 placed on both sides of the display area AA, while the first-second scan lines GL12i, GL12j, and GL12k are driven by a single feeding method that receives scan signal SC12 from a single gate driver 20 placed on one side of the display area AA.

In this embodiment, the first-first scan lines GL11i, GL11j, and GL11k and the first-second scan lines GL12i, GL12j, and GL12k have load variations due to the material composition or feeding method, and thus the scan signals SC11 and SC12 applied through the first-first scan lines GL11i, GL11j, and GL11k, and the first-second scan lines GL12i, GL12j, and GL12k may have different RC delays. That is, the first-first scan signal SC11 applied through the first-first scan lines GL11i, GL11j, and GL11k with a smaller load may have a lower RC delay, while the first-second scan signal SC12 applied through the first-second scan lines GL12i, GL12j, and GL12k, which are driven with a larger load and a single feeding method, may have a higher RC delay.

More specifically, in the second region A2, the first-first scan line GL11i and the first-second scan line GL12i have different loads. Therefore, in the second region A2, the first-first scan signal SC11 and the second scan signal SC12 may have different RC delays.

On the other hand, in the first region A1, since the first-first scan line GL11i and the first-second scan line GL12i are electrically connected, the load variation is compensated. That is, in the first region A1, the first-first scan signal SC11 and the second scan signal SC12 may have substantially the same RC delay.

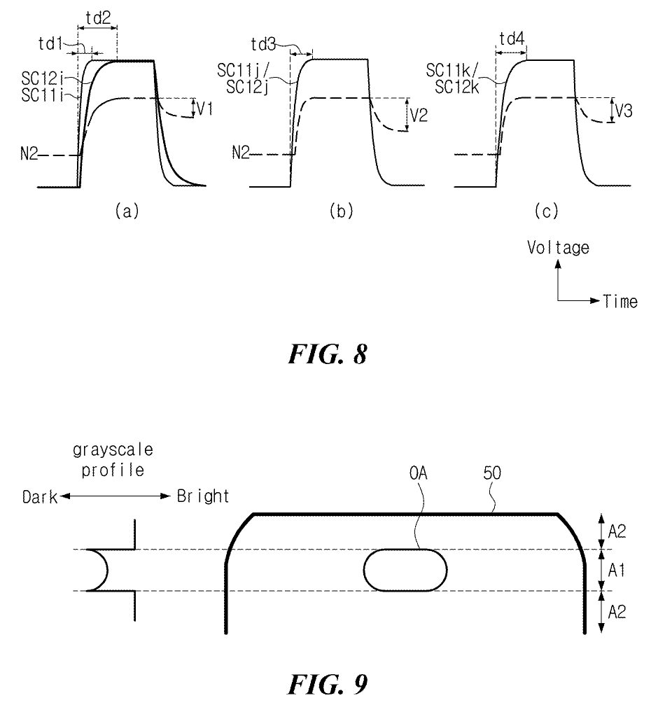

FIG. 8 is a diagram for explaining the kickback variation of the second node due to RC delay differences. FIG. 9 is a diagram illustrating the luminance distribution between pixel rows around the optical region.

Referring to both FIG. 6 and (a) of FIG. 8, in the second region A2, the first-first scan signal SC11i and the first-second scan signal SC12i may have different RC delays. Specifically, the first-first scan signal SC11i may have a first RC delay td1, and the first-second scan signal SC12i may have a second RC delay td2 that is greater than the first RC delay td1. Referring to FIGS. 2 and 3, when the first scan signals SC11i and SC12i transition from a high level to a low level, the voltage of the second node N2 may experience kickback due to coupling, but since a certain amount of leakage current is applied to the second node N2 during the relatively long RC delay time ((td1 + td2)/2), the kickback voltage (hereinafter referred to as the first kickback voltage V1) may be relatively small.

Referring to FIG. 6 and (b) of FIG. 8, in the first region A1, the first-first scan signal SC11j and the first-second scan signal SC12j may have substantially the same RC delay. Specifically, the first-first scan signal SC11j and the first-second scan signal SC12j may have a third RC delay td3. In this case, since the length of the first-first scan line GL11j in the first region A1 is longer than the length of the first-first scan line GL11i in the second region A2, the third RC delay td3 may be larger than the first RC delay td1. Specifically, the third RC delay td3 may be larger than the first RC delay td1 and smaller than the second RC delay td2 (e.g., dt2 > (dt1 + dt2)/2 > dt3 > dt1).

When the first scan signals SC11j and SC12j transition from a high level to a low level, the voltage of the second node N2 may experience kickback due to coupling. In this case, since the relatively short RC delay time d3 prevents leakage current to the second node N2, the kickback voltage (hereinafter referred to as the second kickback voltage V2) may be larger than the first kickback voltage V1.

Referring to FIG. 6 and (c) of FIG. 8, in the first region A1, the first-first scan signal SC11k and the first-second scan signal SC12k may have substantially the same RC delay. Specifically, the first-first scan signal SC11k and the first-second scan signal SC12k may have a fourth RC delay td4. In this case, since the length of the first-first scan line GL11k is longer than the length of the first-first scan line GL11j, the fourth RC delay td4 may be larger than the third RC delay td3. Specifically, the fourth RC delay td4 may be larger than the third RC delay td3 and smaller than the second RC delay td2 (e.g., dt2 > (dt1 + dt2)/2 > dt4 > dt3 > dt1).

When the first scan signals SC11k and SC12k transition from a high level to a low level, the voltage of the second node N2 may experience kickback due to coupling. In this case, since the relatively long RC delay time td4 may apply some leakage current to the second node N2, the kickback voltage (hereinafter referred to as the third kickback voltage V3) may be smaller than the second kickback voltage V2.

As described above, the magnitude of the kickback voltage of the second node N2 is generally inversely proportional to the RC delay of the first scan signals SC11 and SC12. That is, as the RC delay increases, the magnitude of the kickback voltage decreases, resulting in a reduction in luminance degradation. Among the first to third kickback voltages (V1, V2, and V3), the second kickback voltage V2 > the third kickback voltage V3 > the first kickback voltage V1, and accordingly, the pixel rows around the optical area OA exhibit the luminance distribution as shown in FIG. 9.

Referring to FIG. 9, in the second region A2, the pixels may emit light at the required luminance. On the other hand, in the first region A1, the pixels may emit light at a lower luminance than required. In this case, the closer to the edge region of the optical area OA in the column direction, the greater the luminance degradation, and the closer to the central region of the optical area OA in the column direction, the smaller the luminance degradation. Such luminance degradation may cause line dimming (Line Dim) around the optical area OA, leading to a deterioration in image quality (HiAA Line Dim; HLD).

To prevent this phenomenon, by intentionally forming a predetermined RC delay in the first scan signals SC11 and SC12 applied to the pixels of the first region A1, line dimming can be improved. A detailed description is provided hereinafter.

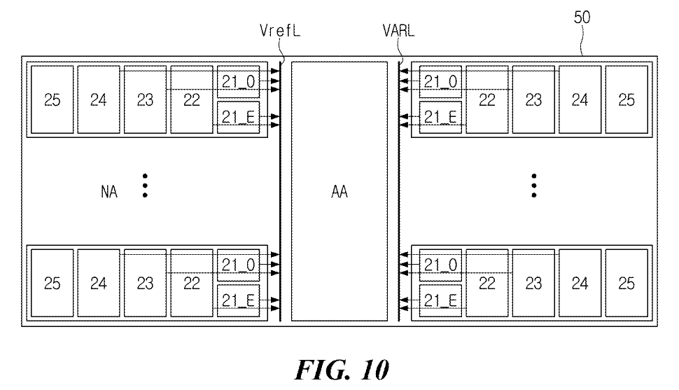

FIG. 10 is a block diagram illustrating the configuration of a gate driver according to an embodiment.

Referring to FIG. 10, the display panel 50 may include a display area AA where an image is displayed, and a non-display area around the display area AA where no image is displayed.

The display area AA includes an array of pixels PX (FIG. 1). The non-display area may include at least part of the driving unit mounted or connected. For example, the gate driver 20 may be positioned at one side of the display area AA or, as illustrated, on both sides (e.g., left or right) in the non-display area. The gate driver 20 arranged on both sides of the non-display area may be configured symmetrically (in a mirrored form). Hereinafter, the configuration will be described based on the gate driver 20 arranged on the left side of the display area AA.

The gate driver 20 may be composed of first to fifth shift registers 21 to 25.

The first to third shift registers 21 to 23 form the scan driving circuit 20A (FIG. 1) and are configured to output scan signals SC1, SC2, and SC3 (FIG. 3). For example, the first shift register 21 is a first scan driving unit that sequentially outputs the first scan signals SC11 and SC12 through the first scan lines GL11 and GL12. The second shift register 22 is a second scan driving unit that sequentially outputs the second scan signal SC2 through the second scan lines GL2. The third shift register 23 is a third scan driving unit that sequentially outputs the third scan signal SC3 through the third scan lines GL3.

Each of the first to third shift registers 21 to 23 may be composed of stage circuits connected in series. Each stage circuit is connected to the corresponding scan lines GL1, GL2, and GL3, and may output scan signals SC1, SC2, and SC3 to the scan lines GL1, GL2, and GL3, respectively.

The first to third scan signals SC1, SC2, and SC3 may be used to drive at least one transistor provided in the pixel PX. For example, the first to third scan signals SC1, SC2, and SC3 may be used to program image data DATA (FIG. 1) into the pixel PX, initialize the voltage stored in the pixel PX, or compensate for the characteristics of the circuit element.

The fourth and fifth shift registers 24 and 25 form the light emission driving circuit 20B (FIG. 1) and are configured to output light emission signals EM1 and EM2 (FIG. 3). For example, the fourth shift register 24 is a first light emission control driving unit that outputs the first light emission signal EM1 through the first light emission lines EL1, and the fifth shift register 25 is a second light emission control driving unit that outputs the second light emission signal EM2 through the second light emission lines EL2.

The first and second emission signals EM1 and EM2 may be used to drive at least one transistor provided in the pixel PX. For example, the first and second emission signals EM1 and EM2 may be used to control the emission of the pixel PX.

Each of the first to fifth shift registers 21 to 25 is driven by receiving a corresponding start signal and a corresponding clock signal through at least one start signal line and multiple clock signal lines. In this case, each clock signal may have a different phase.

The clock signals applied to the first to third shift registers 21 to 23 may be applied through adjacent clock signal lines, and the clock signals applied to the fourth and fifth shift registers 24 and 25 may be applied through adjacent clock signal lines. For example, the first to third shift registers 21 to 23 may receive the first and second gate clock signals applied through adjacent clock signal lines, and the fourth and fifth shift registers 24 and 25 may receive the first and second light emission clock signals applied through adjacent clock signal lines. Here, the adjacent clock signal lines may be configured as a pair.

In one embodiment, the first shift register 21 may be positioned adjacent to the display area AA. Here, the first to third shift registers 21 to 23 may be arranged progressively farther away from the display area AA. In one embodiment, the fifth shift register 25 may be disposed at the outermost position, and at this time, the fourth and fifth shift registers 24 and 25 may be arranged progressively farther away from the display area AA.

The first to third shift registers 21 to 23 may be arranged adjacent to either of the fourth or fifth shift registers 24 or 25. For example, the first and second shift registers 21 and 22 may be arranged adjacent to the fourth shift register 24, and the third shift register 23 may be arranged adjacent to the fifth shift register 25. In this embodiment, the fourth shift register 24 may be arranged between the first shift register 21 and the second shift register 22.

In one embodiment, the first shift register 21 may be composed of an odd-numbered first shift register 21_O and an even-numbered first shift register 21_E. As shown in the drawing, the odd-numbered first shift register 21_O and the even-numbered first shift register 21_E may be arranged on both sides of the display area AA.

When the first shift register 21 is divided into the odd-numbered first shift register 21_O and the even-numbered first shift register 21_E for driving, sufficient time required for applying the data voltage Vdata can be secured. Furthermore, by disposing the odd-numbered first shift register 21_O and the even-numbered first shift register 21_E on both sides of the display area AA, the variation in the per-pixel application time of the data voltage Vdata can be reduced. As a result, the driving of the first shift register 21 can ensure sufficient time required for applying the data voltage Vdata, and it can minimize the variation in per-pixel application time, thereby improving the image quality of the display panel.

Two or more shift registers arranged adjacently may share a single gate power line to receive power. For example, the second shift register 22 and the fourth shift register 24 may share a single gate power line, and the third shift register 23 and the fifth shift register 25 may share a single power line. However, this embodiment is not limited to this configuration.

One or more power bus lines VL may be arranged between the gate driver circuit 20 and the display area AA. The power bus lines VL may include, for example, a anode reset voltage line VARL and a reference voltage line VrefL, among others. These power bus lines VL may be connected to the pixels PX arranged in the display area AA via link lines (not shown) that branch from the respective power bus lines VL.

In one embodiment, the power bus lines VL may be arranged symmetrically on both sides of the display area AA. The power bus lines VL may also be arranged on only one side of the display area AA, either left-right or top-bottom.

The power bus lines VL and link lines may be formed from the same material in the same layer as at least some of the source and drain electrodes 140 of the thin-film transistors TFT, and also may be formed from the same material in the same layer as the connecting electrodes 155. Additionally, the power bus lines VL and link lines may be formed from the same material and in the same layer as at least some of the gate electrodes 125, 126, or from the same material and in the same layer as the semiconductor layers 115, 116. Furthermore, the power bus lines VL and link lines may be formed of the same material and in the same layer as at least some of the touch electrode connection lines 192 and 194 or the touch electrodes 195 and 196, or may be made of the same material and in the same layer as the shielding metal 102.

The arrangement of the first to fifth shift registers 21 to 25 is not limited to what is shown. The arrangement of the first to fifth shift registers 21 to 25 may vary within the possible range according to the specifications of the display panel 50, in order to reduce the size of the non-display area and minimize the length and amount of wiring.

Additionally, the first shift register 21 may output the first scan signals SC11, SC12 to only one pixel row connected to each stage circuit, while the second to fifth shift registers 22 to 25 may output common signals to two or more pixel rows connected to each stage circuit. That is, the first shift register 21 connects one pixel row to each stage circuit, and delayed output signals are supplied to each pixel row, while the second to fifth shift registers 22 to 25 connect two adjacent pixel rows to one stage circuit, and the same output signal may be applied in common.

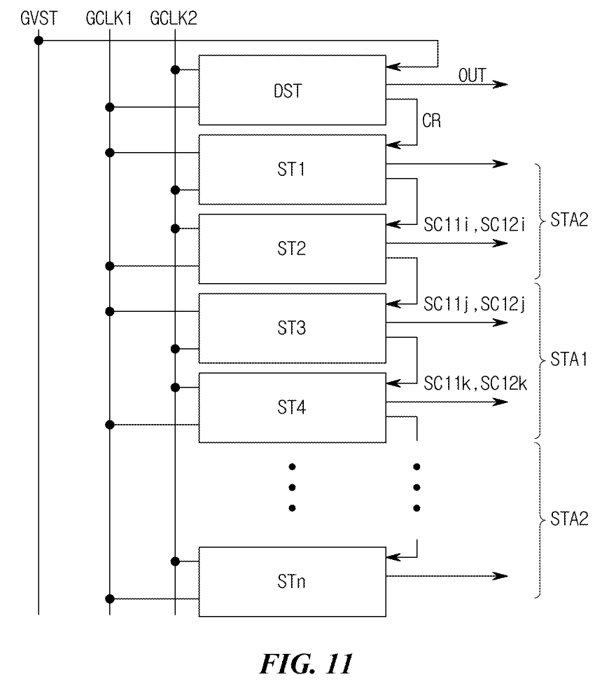

FIG. 11 is a diagram illustrating the configuration of a shift register according to an embodiment. Specifically, FIG. 11 represents the configuration of the first shift register, as shown in FIG. 10.

Referring to FIG. 11, the first shift register 21 may include a plurality of stage circuits ST1 to STn and a dummy stage circuit DST. For convenience of explanation, FIG. 11 shows the first shift register 21 as including one dummy stage circuit DST and n stage circuits ST1 to STn, without being limited to the shown configuration. The first shift register 21 may include fewer or more dummy stage circuits and/or stage circuits.

The stage circuits ST1 to STn may be connected in dependence on the dummy stage circuit DST and the preceding stage circuits. For example, the first stage circuit ST1 may be connected in dependence on the dummy stage circuit DST. The second stage circuit ST2 may be connected in dependence on the first stage circuit ST1, the third stage circuit ST3 may be connected in dependence on the second stage circuit ST2, and the fourth stage circuit ST4 may be connected in dependence on the third stage circuit ST3.

The stage circuits ST1 to STn may have substantially the same configuration. The dummy stage circuit DST and the stage circuits ST1 to STn may have the same or different configurations.

The dummy stage circuit DST and the stage circuits ST1 to STn are configured to receive the start signal GVST and the gate clock signals GCLK1 and GCLK2. In the illustrated embodiment, two gate clock signals GCLK1 and GCLK2 are applied to the dummy stage circuit DST and the stage circuits ST1 to STn, but the embodiment is not limited to this configuration, and a greater or fewer number of clock signals may be provided to the dummy stage circuit DST and the stage circuits ST1 to STn.

The gate clock signals GCLK1 and GCLK2 may have the same waveform and be clock signals with phase shifts at a predetermined interval. For example, the first gate clock signal GCLK1 may have no phase shift, while the second gate clock signal GCLK2 may have a phase shift of 1/2 cycle relative to the first gate clock signal GCLK1. The dummy stage circuit DST and the stage circuits ST1 to STn may be configured to receive a corresponding one of the gate clock signals GCLK1 and GCLK2.

The dummy stage circuit DST is configured to receive the start signal GVST. Each of the stage circuits ST1 to STn may be configured to receive the carry signal CR from either the dummy stage circuit DST or the preceding stage circuit ST1 to STn-first. For example, the first stage circuit ST1 may receive the carry signal CR output by the dummy stage circuit DST. The subsequent stage circuits ST2 to STn may receive the carry signal CR from the preceding stage circuit ST1 to STn-1.

Each of the stage circuits ST1 to STn may output a gate signal or emission signal to the corresponding output lines OUT. Each of the stage circuits ST1 to STn may be pulled up by one of the gate clock signals GCLK1 and GCLK2, and output the gate clock signal GCLK1 or GCLK2. Additionally, Each of the stage circuits ST1 to STn may output the carry signal CR to the next connected stage circuit.

Each of the stage circuits ST1 to STn may be reset by being pulled down by the other gate clock signal GCLK1 or GCLK2.

At least some of the stage circuits ST1 to STn shown in FIG. 11 may apply the first scan signal SC11 and SC12 to the pixels in the first region A1 shown in FIG. 9, while the remaining stage circuits may apply the first scan signal SC11 and SC12 to the pixels in the second region A2 shown in FIG. 9. In this embodiment, the stage circuits that apply the first scan signal SC11 and SC12 to the pixels in the first region A1 are referred to as the first group of stage circuits STA1, while the others are referred to as the second group of stage circuits STA2.

The first group of stage circuits STA1 refers to the stage circuits configured to apply the first scan signal SC11 and SC12 to pixel rows arranged parallel to the optical area OA in the row direction. This first group of stage circuits STA1 applies the first scan signals SC11 and SC12 to the first scan lines GL11 and GL12, which extend in a curved manner along the outer edge of the optical area OA.

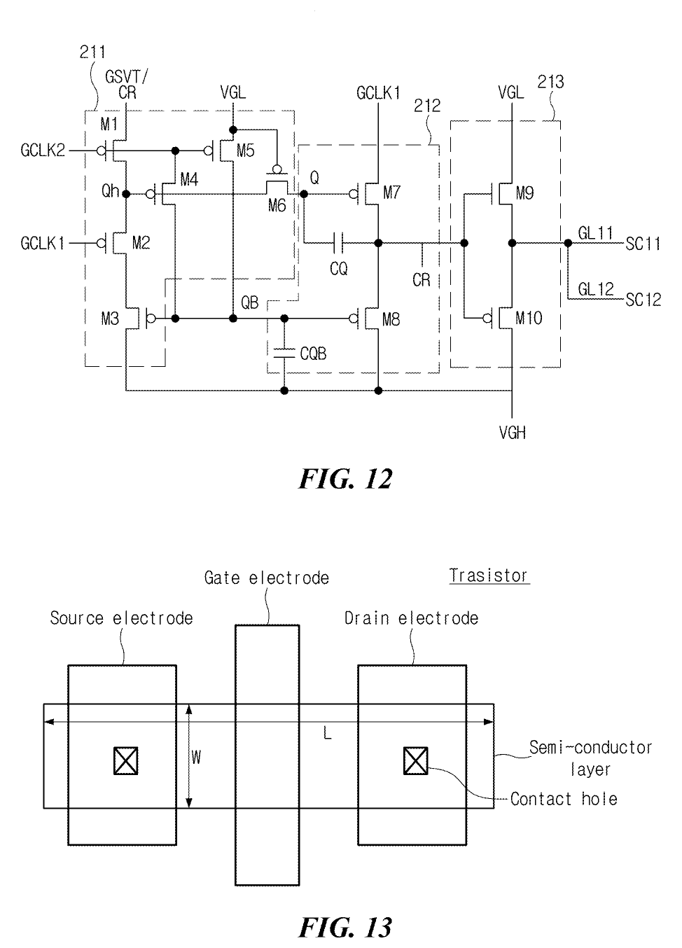

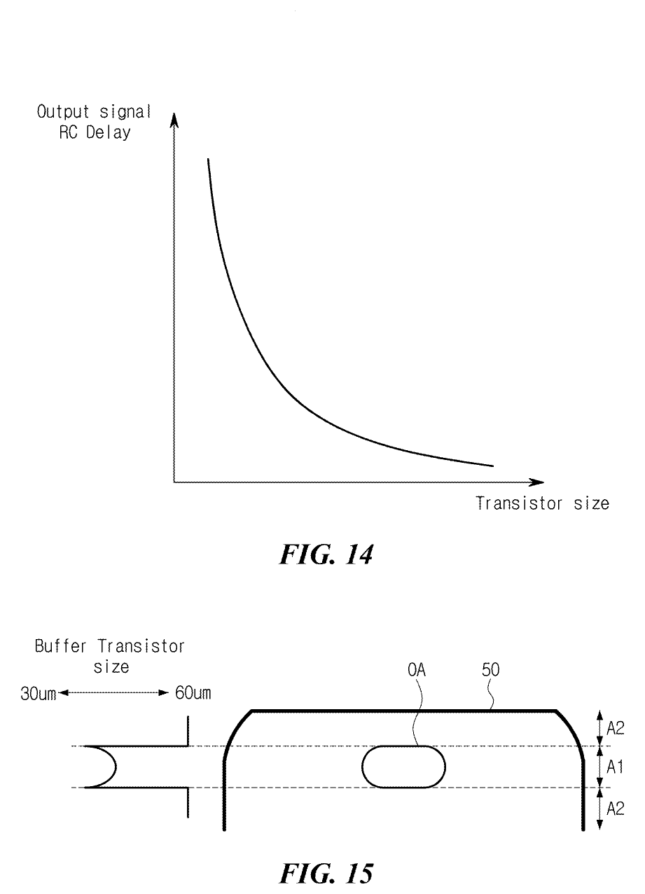

FIG. 12 is a circuit diagram illustrating the configuration of the stage circuit according to an embodiment. FIG. 13 is a plan view illustrating the structure of the transistor according to an embodiment. FIG. 14 is a graph illustrating the relationship between the size (area) of a transistor and the RC delay of the output signal according to an embodiment. FIG. 15 is a diagram illustrating the size distribution of the transistor between cascaded stage circuits according to an embodiment.

Specifically, FIG. 12 shows one of the stage circuits ST1 to STn of the first shift register 21 shown in FIG. 11. FIG. 13 is a plan view illustrating the structure of the transistor according to an embodiment.

Referring to FIG. 12, the stage circuit includes the Q node, QB node, and Qh node. Additionally, the stage circuit includes a node control section 211 and output buffer sections 212 and 213.

The node control section 211 discharges the Qh node and QB node to a low level or charges them to a high level in response to the gate clock signals GCLK1 and GCLK2. The node control section 211 may include transistors M1 to M6.

The first transistor M1 is connected between the carry signal CR input of the preceding stage circuit and the Qh node. For example, in response to the second gate clock signal GCLK2, the first transistor M1 sets the Qh node to the voltage level of the start signal GSVT or the carry signal CR of the preceding stage circuit. When the second gate clock signal GCLK2 is at a low level, the first transistor M1 is turned on, allowing the first transistor M1 to charge or discharge the Qh node to the level corresponding to the start signal GSVT or the carry signal CR of the preceding stage circuit.

The second transistor M2 is connected between the Qh node and the third transistor M3. The second transistor M2 may electrically connect the Qh node and the third transistor M3 in response to the first gate clock signal GCLK1. When the first gate clock signal GCLK1 is at a low level, the second transistor M2 is turned on, electrically connecting the Qh node and the third transistor M3.

The third transistor M3 is connected between the second transistor M2 and the gate high voltage VGH. The third transistor M3 may electrically connect the second transistor M2 and the gate high voltage VGH in response to the voltage of the QB node. When the first gate clock signal GCLK1 is applied at a low level and the QB node voltage discharges to a low level, the second transistor M2 and the third transistor M3 are turned on, allowing the Qh node to be charged to the gate high voltage VGH.

The fourth transistor M4 is connected, for example, between the second gate clock signal GCLK2 and the QB node. The fourth transistor M4 may set the QB node to the voltage level corresponding to the second gate clock signal GCLK2 in response to the voltage of the Qh node. When the Qh node discharges to a low level, the fourth transistor M4 is turned on, charging the QB node to the voltage level corresponding to the second gate clock signal GCLK2, for example, a high level.

The fifth transistor M5 is connected between the gate low voltage VGL and the QB node. The fifth transistor M5 may discharge the QB node to the gate low voltage VGL in response to, for example, the second gate clock signal GCLK2. When the second gate clock signal GCLK2 is at a low level, the fifth transistor M5 is turned on, allowing the fifth transistor M5 to discharge the QB node to the gate low voltage VGL.

The sixth transistor M6 is connected between the Qh node and the Q node. The sixth transistor M6 remains turned on by the gate low voltage VGL, electrically connecting the Qh node and the Q node. Therefore, the voltage of the Q node is controlled to be the same as the voltage of the Qh node, and the voltage is more stably maintained through the sixth transistor M6.

The carry output buffer section 212 includes the seventh transistor M7 and the eighth transistor M8 and capacitors CQ and CQB.

The seventh transistor M7 is connected, for example, between the first gate clock signal GCLK1 and the first output node. The seventh transistor M7 turns on when the voltage of the Q node discharges to a low level and, based on the first gate clock signal GCLK1, outputs the low-level carry signal CR through the first output node.

A first capacitor CQ is connected between the gate and source of the seventh transistor M7. When the carry signal CR is output, the first capacitor CQ bootstraps the voltage of the Q node to a voltage level lower than the low level of the carry signal CR, in synchronization with the low-level carry signal CR. Once the voltage of the Q node is bootstrapped, the low-voltage level of the first gate clock signal GCLK1 may be output quickly and without distortion.

The eighth transistor M8 is connected between the first output node and the gate high voltage VGH. The eighth transistor M8 turns on when the QB node is at a low level, outputting the high-level carry signal CR through the first output node, based on the gate high voltage VGH.

A second capacitor CQB is connected between the gate and source of the eighth transistor M8. When the carry signal CR is output, the second capacitor CQB bootstraps the voltage of the QB node to a boosted voltage level higher than the gate high voltage VGH, in synchronization with the high-level carry signal CR. Once the voltage of the QB node is bootstrapped, the high-voltage level of the gate high voltage VGH may be output quickly and without distortion.

The gate output buffer section 213 includes the ninth transistor M9 and the tenth transistor M10.

The ninth transistor M9 is connected, for example, between the gate low voltage VGL and the second output node. The ninth transistor M9 turns on when the high-level carry signal CR is output, and based on the gate low voltage VGL, outputs the low-level first scan signals SC11 and SC12 through the second output node. The ninth transistor M9 outputs the low-level first scan signals SC11 and SC12, and it may be named as a pull-down transistor that turns off the first transistor T1 in FIG. 2.

The tenth transistor M10 is connected between the second output node and the gate high voltage VGH. The tenth transistor M10 turns on when the low-level carry signal CR is output, and based on the gate high voltage VGH, outputs the high-level first scan signals SC11, SC12 through the first output node. The tenth transistor M10 may be named as a pull-up transistor that outputs the high-level first scan signals SC11 and SC12, and turns on the first transistor T1 in FIG. 2.

In one embodiment, the size of the transistors M9, M10 (hereinafter referred to as buffer transistors) in the gate output buffer section 213 may differ between the stage circuits ST1 to STn. Specifically, between the first group stage circuit STA1 and the second stage circuit STA2 in FIG. 9, the size of the buffer transistors M9 and M10 may differ.

Here, the size of the buffer transistors M9, M10 may refer to the width W of the semiconductor layer shown in FIG. 13, but is not limited to this. The size of the buffer transistors M9, M10 may also refer to the length L of the semiconductor layer, and may further include at least one of the source, drain, or gate electrodes.

The size of the buffer transistors M9, M10 is controlled to vary the RC delay of the first scan signals SC11 and SC12 output through the buffer transistors M9, M10. Typically, as the width W of the transistor decreases, the RC delay of the signal output through the transistor increases. That is, as shown in FIG. 14, the width W of the transistor and the RC delay of the output signal are generally inversely proportional.

In the first group stage circuit STA1, the width W of the buffer transistors M9 and M10 may be designed relatively small to increase the RC delay of the output signal. As a result, the width W of the buffer transistors M9 and M10 in the first group stage circuit STA1 may be smaller than that in the second group stage circuit STA2. For example, the width W of the buffer transistors M9 and M10 in the first group stage circuit STA1 may be approximately 30 µm, and the width W in the second group stage circuit STA2 may be approximately 60 µm, but this is not limited.

As the size of the buffer transistors M9 and M10 is reduced, the RC delay of the first scan signals SC11 and SC12 increases, which may cause the kick-back voltage of the second node N2 to decrease, as described with reference to FIG. 8. As a result, by controlling the size of the buffer transistors M9 and M10, the luminance degradation in the first region A1 may be improved.

In one embodiment, the size of the buffer transistors M9 and M10 may vary between the first group stage circuits STA1. For example, between the first group stage circuits STA1, the size of the buffer transistors M9 and M10 may gradually vary.

As described with reference to FIG. 8 and FIG. 9, the luminance in the first region A1 may gradually vary. In this case, the luminance degradation is greatest at the edge in the column direction of the first region A1 and relatively smaller in the central area. Therefore, the RC delay of the first scan signals SC11 and SC12 should be controlled to be the largest in the area with the greatest luminance degradation.

In this embodiment, among the first group stage circuits STA1, the size of the buffer transistors M9 and M10 may be the smallest in the first stage circuit among the first group stage circuits STA1, gradually increasing in the subsequent stage circuit among the first group stage circuits STA1 connected in cascade, and reaching the largest size in the middle stage circuit STA1 among the first group stage circuits STA1 connected in cascade. Then, the size of the buffer transistors M9 and M10 may gradually decrease again. In the last stage circuit among the first group stage circuits STA1, the size of the buffer transistors M9 and M10 may be the same as in the first stage circuit among the first group stage circuits STA1. This distribution of the sizes of the buffer transistors M9 and M10 is illustrated as shown in FIG. 15. That is, among the first group stage circuits STA1 connected in cascade, the buffer transistors M9 and M10 in the first and last stage circuits may be designed to have the smallest size, while the buffer transistors M9 and M10 in the middle stage circuit may be designed to have the largest size.

In one embodiment, the size of some or all of the buffer transistors M9 and M10 may be variable. For example, as a buffer transistor that affects the kick-back voltage of the second node N2, the size of the pull-down transistor M9, which controls the turn-off RC delay of the first scan signals SC11 and SC12, may be varied according to the above-described embodiment. However, the embodiment is not limited thereto.

Meanwhile, the embodiment in which the size of the buffer transistors M9 and M10 is variable may be applied to the first shift register 21 that outputs the first scan signals SC11 and SC12. Since the second to fifth shift registers 22 to 25 do not form a kick-back voltage for the second node N2, the embodiment in which the size of the buffer transistors is variable may not be applied. In this embodiment, the size of the buffer transistors in the second to fifth shift registers 22 to 25 may be the same across all stage circuits, but this is not limited. The size of the buffer transistors in the second to fifth shift registers 22 to 25 may be the same as the size of the buffer transistors in the second group stage circuit STA2 (e.g., approximately 60um), without being limited thereto.

The display device according to the embodiments is advantageous for improving display quality by reducing luminance degradation and black dimming caused by differences in RC delay around the optical region in a HiAA structure.

The display device according to the embodiments is advantageous for allowing image display across the entire front surface of the display area, facilitating a narrow-bezel or bezel-less design to enhance aesthetics, and reducing the size and weight of the display device.

Although embodiments of this disclosure have been described above with reference to the accompanying drawings, it will be understood that the technical configuration of this disclosure described above can be implemented in other specific forms by those skilled in the art without changing the technical concept or essential features of the present disclosure. Therefore, it should be understood that the embodiments described above are exemplary and not limited in all respects. Furthermore, it should be understood that all modifications or variations derived from the meaning and scope of the claims and their equivalent concept are included within the scope of the disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

Claims:

1. A display device comprising:
a display panel comprising a display area including pixels disposed therein, an optical area disposed within the display area, and a non-display area surrounding the display area; and
a gate driver disposed in the non-display area and configured to apply scan signals to the pixels through a plurality of scan lines via a plurality of stage circuits connected in a cascade,
wherein each of the plurality of stage circuits comprises:
a node controller configured to charge or discharge a Q node and a QB node in response to gate clock signals; and
an output buffer including at least one buffer transistor and configured to output a gate high voltage or a gate low voltage as the scan signal in response to voltages of the Q node and the QB node,
wherein the plurality of stage circuits include first group stage circuits and second group stage circuits, and a size of the at least one buffer transistor in the first group stage circuits is smaller than a size of the at least one buffer transistor in the second group stage circuits.

2. The display device of claim 1, wherein the display area comprises:
a first region overlapping with the optical area in a row direction; and
a second region surrounding the first region,
wherein the first group stage circuits are configured to apply the scan signal to pixels disposed in the first region, and the second group stage circuits are configured to apply the scan signal to pixels disposed in the second region.

3. The display device of claim 2, wherein the size of the at least one buffer transistor among the first group stage circuits varies gradually.

4. The display device of claim 2, wherein, among the first group stage circuits connected in a cascade, the size of the buffer transistor increases gradually and then decreases gradually.

5. The display device of claim 2, wherein the size of the buffer transistor is inversely proportional to a resistive-capacitive (RC) delay of the scan signal.

6. The display device of claim 5, wherein each of the pixels comprises:
a light-emitting element;
a driving transistor connected between a high-potential driving voltage line and the light-emitting element, with a gate electrode connected to a second node; and
a switching transistor connected between a data line and the second node, with a gate electrode configured to receive the scan signal,
wherein, based on a level of the scan signal transitioning, a voltage pre-stored at the second node is kicked back by a predetermined kickback voltage.

7. The display device of claim 6, wherein a magnitude of the kickback voltage is inversely proportional to the RC delay of the scan signal.

8. The display device of claim 6, wherein the switching transistor has a dual-gate structure comprising a top gate electrode and a bottom gate electrode.

9. The display device of claim 8, wherein each of the pixels further comprises an emission transistor connected between the high-potential driving voltage line and the driving transistor,
wherein the switching transistor is an oxide thin-film transistor, and the emission transistor is an low temperature poly-silicon (LTPS) thin-film transistor.

10. The display device of claim 9, further comprising:
a substrate;
a first insulating layer disposed on the substrate;
a first semiconductor layer of the emission transistor disposed on the first insulating layer;
a second insulating layer disposed on the first semiconductor layer;
a gate electrode of the emission transistor disposed on the second insulating layer;
a third insulating layer disposed on the gate electrode of the emission transistor;
the bottom gate electrode of the switching transistor disposed on the third insulating layer;
a fourth insulating layer disposed on the bottom gate electrode;
a second semiconductor layer of the switching transistor disposed on the fourth insulating layer;
a fifth insulating layer disposed on the second semiconductor layer;
the top gate electrode of the switching transistor disposed on the fifth insulating layer;
a sixth insulating layer disposed on the top gate electrode of the switching transistor; and
source and drain electrodes of the emission transistor and the switching transistor disposed on the sixth insulating layer.

11. The display device of claim 10, wherein the bottom gate electrode includes a high-resistance material, and the top gate electrode includes a low-resistance material.

12. The display device of claim 9, wherein each of the plurality of scan lines comprises:
a first scan line including a low-resistance material and connected to the top gate electrode; and
a second scan line including a high-resistance material and connected to the bottom gate electrode.

13. The display device of claim 12, wherein, in the first region, the first scan line and the second scan line are electrically connected through a contact hole.

14. The display device of claim 13, wherein, in the first region, the first scan line extends in a curved manner along an outer circumference of the optical area.

15. The display device of claim 14, wherein, in the first region, the first scan lines have different lengths.

16. The display device of claim 15, wherein the RC delay of the scan signal is proportional to the length of the scan line.

17. The display device of claim 14, wherein the second scan line is segmented into a plurality of portions on both sides of the optical area, and the segmented plurality of portions are electrically connected to the first scan line through the contact hole on both sides of the optical area.
